(19) United States
(12) Patent Application Publication
(10) Pub. No.: US 2026/0068347 A1
(43) Pub. Date: Mar. 5, 2026

(54) SEMICONDUCTOR DEVICE, ELECTRONIC APPARATUS, AND SEMICONDUCTOR DE-VICE MANUFACTURING METHOD

(71) Applicant: SONY SEMICONDUCTOR SOLUTIONS CORPORATION, Kanagawa (JP)

(72) Inventors: Akihisa SAKAMOTO, Kanagawa (JP); Yusaku SUGIMORI, Kanagawa (JP)

(73) Assignee: SONY SEMICONDUCTOR SOLUTIONS CORPORATION, Kanagawa (JP)

(21) Appl. No.: 19/105,914

(22) PCT Filed: Aug. 30, 2023
(86) PCT No.: PCT/JP2023/031374

§ 371 Date: Feb. 24, 2025

(30) Foreign Application Priority Data
Sep. 5, 2022 (JP) 2022-141021

(51) Int. Cl. H10F 39/00; H01L 23/00

(52) U.S. Cl. CPC H10F 39/811; H10F 39/018; H10F 39/809

(57) ABSTRACT

A semiconductor device according to one aspect of the present disclosure includes a semiconductor substrate having a first insulating layer and a plurality of first terminals provided on the first insulating layer, and a semiconductor element laminated on the semiconductor substrate and having a second insulating layer and a plurality of second terminals provided on the second insulating layer and connected to the plurality of first terminals, respectively. The first insulating layer or the second insulating layer includes a third insulating layer formed of a material different from a material of the first insulating layer and bonding the semiconductor substrate and the semiconductor element.

### FIELD

The present disclosure relates to a semiconductor device, an electronic apparatus, and a semiconductor device manufacturing method.

### BACKGROUND

In various semiconductor devices such as a solid-state imaging device, a light emitting device, and a storage device, a chip on wafer (CoW) technology is used (e.g., Patent Literature 1.). In this CoW technology, chips are laminated and bonded on a wafer. The chip has a plurality of pads (e.g., Cu pad) each functioning as a terminal. Downsizing of the chip is progressing, and a pitch of each pad is narrowed due to an influence of the downsizing of the chip.

### CITATION LIST

### Patent Literature

Patent Literature 1: WO 2019/087764 A

### SUMMARY

### Technical Problem

When a bonding strength on a bonding surface is insufficient between a chip and a wafer, a bonding failure, film elevation, or the like may occur during a heating process in a subsequent-process. A pad region and an insulating region are mixed on the bonding surface, and the bonding strength tends to be insufficient at a portion where the insulating region occupies a large area. For example, when the chip is small, the bonding strength tends to decrease as compared with a case where the chip is large.

Therefore, the present disclosure provides a semiconductor device, an electronic apparatus, and a semiconductor device manufacturing method capable of improving the bonding strength.

### Solution to Problem

A semiconductor device according to an aspect of the present disclosure includes: a semiconductor substrate including a first insulating layer and a plurality of first terminals provided on the first insulating layer; and a semiconductor element laminated on the semiconductor substrate, the semiconductor element including a second insulating layer and a plurality of second terminals provided on the second insulating layer and connected to the plurality of first terminals, respectively, wherein the first insulating layer or the second insulating layer includes a third insulating layer formed of a material different from a material of the first insulating layer and bonding the semiconductor substrate and the semiconductor element.

An electronic apparatus according to an aspect of the present disclosure includes a semiconductor device, the semiconductor device including: a semiconductor substrate having a first insulating layer and a plurality of first terminals provided on the first insulating layer; and a semiconductor element laminated on the semiconductor substrate, the semiconductor element having a second insulating layer and a plurality of second terminals provided on the second insulating layer and connected to the plurality of first terminals, respectively, wherein the first insulating layer or the second insulating layer includes a third insulating layer formed of a material different from a material of the first insulating layer and bonding the semiconductor substrate and the semiconductor element.

A semiconductor device manufacturing method according to an aspect of the present disclosure includes: laminating, on a semiconductor substrate having a first insulating layer and a plurality of first terminals provided on the first insulating layer, a semiconductor element having a second insulating layer and a plurality of second terminals provided on the second insulating layer and connected to the plurality of first terminals, respectively, wherein the laminating the semiconductor element on the semiconductor substrate includes bonding the semiconductor substrate and the semiconductor element by a third insulating layer formed of a material different from the first insulating layer and included in the first insulating layer or the second insulating layer.

### BRIEF DESCRIPTION OF DRAWINGS

FIG. 1 is a cross-sectional view illustrating a configuration example of a semiconductor device according to a first embodiment.

FIG. 2 is a plan view illustrating a configuration example of the semiconductor device according to the first embodiment.

FIG. 3 is a diagram illustrating stress relaxation by a bonding surface material according to the first embodiment.

FIG. 4 is a diagram illustrating a manufacturing process of the semiconductor device according to the first embodiment.

FIG. 5 is a diagram illustrating a manufacturing process of a semiconductor element according to the first embodiment.

FIG. 6 is a cross-sectional view illustrating a configuration example of a semiconductor device according to a second embodiment.

FIG. 7 is a diagram illustrating a manufacturing process of the semiconductor device according to the second embodiment.

FIG. 8 is a diagram illustrating a manufacturing process of a semiconductor element according to the second embodiment.

FIG. 9 is a cross-sectional view illustrating a configuration example of a semiconductor device according to a third embodiment.

FIG. 10 is a diagram illustrating a manufacturing process of the semiconductor device according to the third embodiment.

FIG. 11 is a diagram illustrating the manufacturing process of the semiconductor device according to the third embodiment.

FIG. 12 is a cross-sectional view illustrating a configuration example of a semiconductor device according to a fourth embodiment.

FIG. 13 is a diagram illustrating a manufacturing process of the semiconductor device according to the fourth embodiment.

FIG. 14 is a cross-sectional view illustrating a configuration example of a semiconductor device according to a fifth embodiment.

FIG. 15 is a plan view illustrating the configuration example of the semiconductor device according to the fifth embodiment.

FIG. 16 is a diagram illustrating a manufacturing process of the semiconductor device according to the fifth embodiment.

FIG. 17 is a diagram illustrating the manufacturing process of the semiconductor device according to the fifth embodiment.

FIG. 18 is a cross-sectional view illustrating a configuration example of a semiconductor device according to a sixth embodiment.

FIG. 19 is a plan view illustrating the configuration example of the semiconductor device according to the sixth embodiment.

FIG. 20 is a diagram illustrating a manufacturing process of the semiconductor device according to the sixth embodiment.

FIG. 21 is a diagram illustrating the manufacturing process of the semiconductor device according to the sixth embodiment.

FIG. 22 is a perspective view illustrating a configuration example of a semiconductor device according to a seventh embodiment.

FIG. 23 is a cross-sectional view illustrating the configuration example of the semiconductor device according to the seventh embodiment.

FIG. 24 is a cross-sectional view illustrating a circuit example of the semiconductor device according to the seventh embodiment.

FIG. 25 is a diagram illustrating a circuit example of a comparator according to the seventh embodiment.

FIG. 26 is a diagram illustrating an output example of the comparator according to the seventh embodiment.

FIG. 27 is a perspective view illustrating a configuration example of a semiconductor device according to an eighth embodiment.

FIG. 28 is a cross-sectional view illustrating the configuration example of the semiconductor device according to the eighth embodiment.

FIG. 29 is a perspective view illustrating exemplary regions of a pixel region and a connection region of the semiconductor device according to the eighth embodiment.

FIG. 30 is a plan view illustrating a configuration example of wiring of the semiconductor device according to the eighth embodiment.

FIG. 31 is a diagram illustrating a circuit example of the semiconductor device according to the eighth embodiment.

FIG. 32 is a diagram illustrating another circuit example of the semiconductor device according to the eighth embodiment.

FIG. 33 is a diagram illustrating an application example using the semiconductor device according to each embodiment.

FIG. 34 is a diagram illustrating a configuration example of an imaging device according to the application example.

FIG. 35 is a diagram illustrating a configuration example of a distance measuring device according to the application example.

### DESCRIPTION OF EMBODIMENTS

Hereinafter, embodiments of the present disclosure will be described with reference to the drawings. Note that a device, apparatus, method, and the like according to the present disclosure are not limited by the embodiments. In the following embodiments, same parts are basically given the same reference signs to omit redundant description.

In the description below, one or more embodiments (including examples and modifications) may be implemented independently. On the other hand, at least some of the plurality of embodiments described below may be appropriately combined with at least some of other embodiments. The plurality of embodiments may include novel features different from each other. Therefore, the plurality of embodiments can contribute to solving different objects or problems, and can exhibit different effects. Note that the effects in each embodiment are merely examples and are not limited, and other effects may be provided.

In addition, the drawings referred to in the following description are drawings for facilitating the description and understanding of an embodiment of the present disclosure, and shapes, dimensions, ratios, and the like illustrated in the drawings may be different from actual ones for the sake of clarity. Furthermore, the elements and the like illustrated in the drawings can be appropriately modified in design in consideration of the following description and known techniques. In addition, in the following description, a vertical direction of a laminate structure of the element and the like corresponds to, for example, a relative direction when a surface of a substrate on which the element is provided is facing upward, and may be different from a vertical direction according to actual gravitational acceleration.

The present disclosure will be described according to the following order of items.
1. First embodiment
1-1. Configuration example of semiconductor device
1-2. Semiconductor device manufacturing method
1-3. Semiconductor element manufacturing method
2. Second embodiment
2-1. Configuration example of semiconductor device
2-2. Semiconductor device manufacturing method
2-3. Semiconductor element manufacturing method
3. Third embodiment
3-1. Configuration example of semiconductor device
3-2. Semiconductor device manufacturing method
4. Fourth embodiment
4-1. Configuration example of semiconductor device
4-2. Semiconductor device manufacturing method
5. Fifth embodiment
5-1. Configuration example of semiconductor device
5-2. Semiconductor device manufacturing method
6. Sixth embodiment
6-1. Configuration example of semiconductor device
6-2. Semiconductor device manufacturing method
7. Seventh embodiment
7-1. Configuration example of semiconductor device
8. Eighth embodiment
8-1. Configuration example of semiconductor device
9. Functions and effects according to each embodiment
10. Application example
11. Electronic apparatus according to application example
11-1. Imaging device
11-2. Distance measuring device
12. Other embodiments
13. Appendix

### 1. First Embodiment

### 1-1. Configuration Example of Semiconductor Device

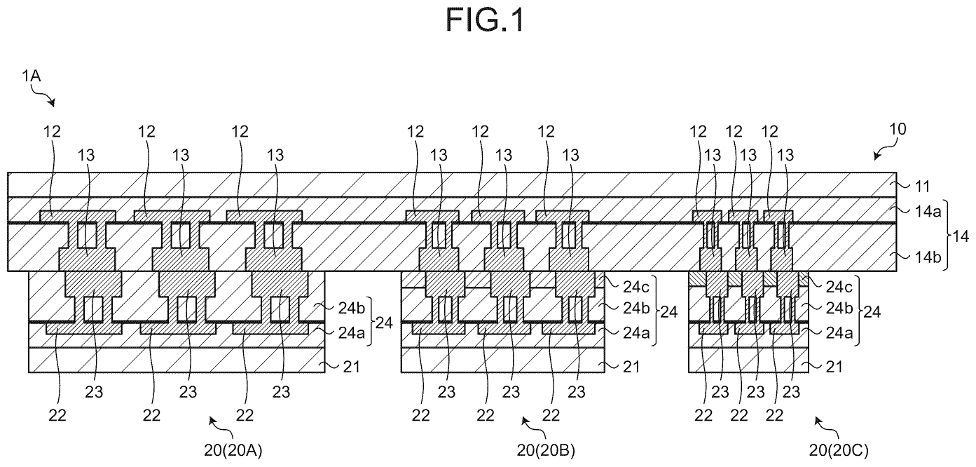

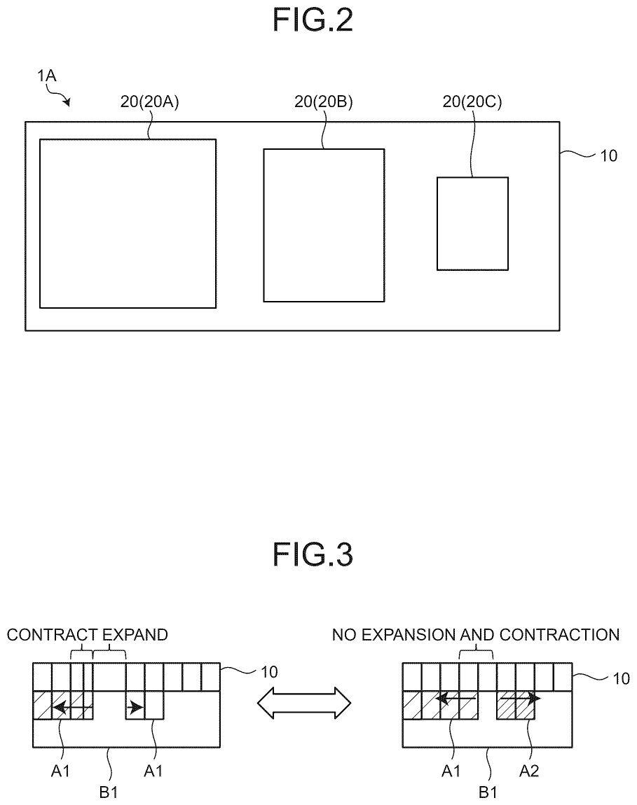

A configuration example of a semiconductor device 1A according to the present embodiment will be described with reference to FIGS. 1 to 3. FIG. 1 is a cross-sectional view illustrating the configuration example of the semiconductor device 1A according to the present embodiment. FIG. 2 is a plan view illustrating the configuration example of the semiconductor device 1A according to the present embodiment. FIG. 3 is a diagram illustrating stress relaxation by a bonding surface material between adjacent chips.

As illustrated in FIG. 1, the semiconductor device 1A according to the present embodiment includes a semiconductor substrate 10 and a plurality of semiconductor elements (semiconductor substrates) 20. Examples of the semiconductor device 1A include various semiconductor devices such as a solid-state imaging device, a light emitting device, and a storage device. Note that FIG. 1 is an example, and necessary members are provided in the semiconductor device 1A illustrated in FIG. 1 so as to complete, for example, a solid-state imaging device, a light emitting device, or a storage device.

The semiconductor substrate 10 includes a substrate 11, a plurality of circuit elements 12, a plurality of terminals (first terminals) 13, and an insulating layer (first insulating layer) 14. Each of the circuit elements 12 is realized by, for example, various elements (e.g., transistor and wiring) configuring a circuit. These circuit elements 12 are provided on the substrate 11. Each terminal 13 is realized by, for example, a pad such as a Cu pad. These terminals 13 are connected to corresponding circuit elements 12 and provided on the substrate 11, and end surfaces (surfaces on a side of the semiconductor element 20) of the terminals 13 are exposed from the insulating layer 14. The insulating layer 14 is provided to be laminated on the substrate 11 so as to ensure insulation of each of the circuit elements 12 and the terminals 13.

The insulating layer 14 includes two insulating layers 14a and 14b. The insulating layers 14a and 14b are laminated on the substrate 11 and are formed of the same material. As a material of these insulating layers 14a and 14b, for example, SiO₂ is used. The insulating layer 14b is located on a surface (bonding surface) of the insulating layer 14 on the side of the semiconductor element 20, and functions as a bonding layer that bonds the semiconductor substrate 10 and the semiconductor element 20.

In the above semiconductor substrate 10, there are a portion where a pitch (separation distance) of the terminal 13 is wide and a portion where the pitch is narrow. In the example in FIG. 1, the pitch (bonding pitch) of the terminal 13 decreases from left to right in an in-plane direction of the semiconductor substrate 10. This pitch is set according to the semiconductor elements 20.

Each of the semiconductor elements 20 includes a substrate 21, a plurality of circuit elements 22, a plurality of terminals (second terminals) 23, and an insulating layer (second insulating layer) 24. The circuit element 22 is realized by, for example, various elements (e.g., transistor and wiring) configuring a circuit. These circuit elements 22 are provided on the substrate 21. Each of the terminals 23 is realized by, for example, a pad such as a Cu pad. These terminals 23 are connected to the corresponding circuit elements 22 and provided on the substrate 21, and end surfaces (surfaces on a side of the semiconductor substrate 10) of the terminals 23 are exposed from the insulating layer 24. The insulating layer 24 is provided to be laminated on the substrate 21 so as to ensure insulation of the circuit elements 22 and the terminals 23.

The above semiconductor element 20 includes a plurality of semiconductor elements 20 (20A, 20B, and 20C) having different sizes, pitches of the terminals 23, and the like. In the example in FIG. 1, in the semiconductor elements 20, the pitch of the terminal 23 narrows from left to right in the in-plane direction of the semiconductor substrate 10. Therefore, as illustrated in FIG. 2, the semiconductor element 20 having the largest plane size and pitch is defined as a first semiconductor element 20A, the semiconductor element 20 having the second largest plane size and pitch is defined as a second semiconductor element 20B, and the semiconductor element 20 having the third largest plane size and pitch (the smallest plane size and pitch) is defined as a third semiconductor element 20C. The semiconductor elements 20A, 20B, and 20C are, for example, a semiconductor element including a logic circuit or a memory circuit.

The insulating layer 24 of the first semiconductor element 20A includes two insulating layers 24a and 24b. Each of the insulating layers 24a and 24b is laminated on the substrate 21 and is formed of the same material. As a material of these insulating layers 24a and 24b, for example, SiO₂ is used. The insulating layer 24b is located on a surface (bonding surface) of the insulating layer 24 on the semiconductor substrate 10 side, and functions as a bonding layer that bonds the semiconductor substrate 10 and the first semiconductor element 20A.

The insulating layers 24 of the second semiconductor element 20B and the third semiconductor element 20C include three insulating layers 24a, 24b, and 24c, respectively. These insulating layers 24a, 24b, and 24c are laminated on the substrate 21. The insulating layers 24a and 24b are formed of the same material, and the insulating layer (third insulating layer) 24c is formed of a material different from the insulating layers 24a and 24b. In other words, a material different from the insulating layer 14b of the semiconductor substrate 10. As a material of the insulating layers 24a and 24b, for example, SiO₂ is used. As a material of the insulating layer 24c, for example, SiN or SiCN is used. The insulating layer 24c is located on a surface (bonding surface) of the insulating layer 24 on the side of the semiconductor substrate 10, and functions as a bonding layer that bonds the semiconductor substrate 10 and the semiconductor elements 20 (20B and 20C).

Here, since the insulating layer 24c is formed of at least the material different from that of the insulating layer 14b of the semiconductor substrate 10, the second semiconductor element 20B and the semiconductor substrate 10 are bonded by materials different from each other. Similarly, the third semiconductor element 20C and the semiconductor substrate 10 are bonded by materials different from each other. The insulating layer 24c of the second semiconductor element 20B and the insulating layer 24c of the third semiconductor element 20C may be made of the same material, or may be made of different materials. In the example in FIG. 1, insulating layer 24b of the first semiconductor element 20A is made of the same material (e.g., SiO2) as the insulating layer 14b of the semiconductor substrate 10. Therefore, the first semiconductor element 20A and the semiconductor substrate 10 are bonded to each other by the same material.

In addition to SiN and SiCN, the material of the insulating layer 24c may include SiO2, Si3N4, SiNxOy, SiOC, GeO2, Ge3N4, SnO2, B2O3, BN, SeO2, TeO2, TeO3, MgO, Mg3N2, AL2O3, AlN, TiO2, TiN, V2O5, MnO, MnO2, Mn2O3, Mn2O7, Mn3O4, FeO, Fe2O3, Fe3O4, CoO, Co3O4, NiO, Ni2O3, CuO, Cu2O, Cu3N, ZnO, CrN, Cr23C6, Cr3C, Cr7C3, Cr3C2, Mo3C2, TiC, Nb4C3, and Ta4C3, ZrC, HfC, V4C3, VC, W2C, WC, Fe3C, Fe7C3, or Fe2C.

Usually, when a bonding strength is insufficient on a bonding surface where Cu (terminal material) and SiO2 (insulating material) coexist, a bonding failure or film elevation may occur during a heating process in a subsequent step. Depending on a size (chip size) of the semiconductor elements 20B and 20C and a density (pad density) of the terminal 23, an occurrence of blister in the heating process can be suppressed by using a bonding film such as SiN or SiCN having a higher bonding strength than SiO2 for the insulating layer 24c. For example, the material of the insulating layer 24c is determined such that the bonding strength between the semiconductor substrate 10 and the semiconductor elements 20 (20A, 20B, and 20C) by the insulating layer 24c increases as the size of the semiconductor elements 20 (20A, 20B, 20C) or the pitch of the terminals 23 is decreased. For the first semiconductor element 20A having a larger size and a larger number of terminals 23 than those of the semiconductor elements 20B and 20C, i.e., the first semiconductor element 20A having no problem in the bonding strength, the insulating film 24b of the SiO2 layer, which has a lower wiring capacitance and is superior in production cost, is directly used as the bonding surface. It has been confirmed by experiments and the like that the use of SiN, SiCN, or the like for the insulating layer 24c of the semiconductor elements 20B and 20C approximately doubles the bonding strength and reduces a blister area from about 30 mm to about 0.2 mm as compared with the case of using SiO2.

In addition, when SiO2 is used for insulation of the terminals 23 with a narrow pitch (narrow-pitch pads), the withstand voltage between the terminals 23 (between the pad and the pad) may be insufficient. For example, in the CoW of each of the semiconductor elements 20B and 20C having the respective terminals 23 with a narrow pitch such as an advanced logic, the bonding film (e.g., SiN and SiCN) corresponding to a required withstand voltage is used as the insulating layer 24c in response to concern of reliability degradation due to insufficient withstand voltage between the respective terminals 23. In addition, the withstand voltage between the terminals 23 can be adjusted by changing the film thickness (length in a direction orthogonal to the plane) or the like of the insulating layer 24c. For example, the film thickness of the insulating layer 24c is determined such that an insulation resistance between the terminals 23 increases as the pitch of the terminals 23 is decreased. Since the first semiconductor element 20A has the terminals 23 with a wide pitch and thus there is no problem in withstand voltage, the insulating film 24b of the SiO2 layer, which has a lower wiring capacitance and is superior in production cost, is directly used as the bonding surface.

In addition, when the adjacent semiconductor elements 20 (chips) have the same bonding material, it is not possible to control distortion caused by a difference in coefficient of thermal expansion (CTE) of each element material between the elements. Therefore, by changing a film type, the film thickness, and the like of the insulating layer 24c with respect to the CTE, size, and layout of the semiconductor elements 20B and 20C, it is possible to alleviate the distortion caused by the CTE described above.

For example, as illustrated in the left diagram of FIG. 3, each chip A1 (semiconductor element 20) manufactured according to a normal process flow is bonded to the semiconductor substrate 10 and then covered with an oxide film B1 (e.g., SiO). By a temperature rise (about 350° C.) at the time of forming the oxide film B1, the chip A1 expands due to the CTE of the chip A1 itself, and is fixed with the oxide film B1 as it is. As illustrated in the left diagram of FIG. 3, the chip A1 expanded tends to contract at the time of cooling at normal temperature, but since the chip A1 is fixed by the oxide film B1, a stress in an arrow direction in the left diagram of FIG. 3 remains in the chip A1. The magnitude of the stress differs. The above strain due to the residual stress is transferred to the side of the semiconductor substrate 10 bonded to the chip A1, and OCL deviation (an example of an additional member) and fluctuation of transistor characteristics (an example of the circuit element 22) may occur. Therefore, as illustrated in the right diagram of FIG. 3, in the chip A2 having the insulating layer 24c as described above, the distortion of the adjacent chips A1 and A2 can be alleviated by changing the film type, the film thickness, and the like of the insulating layer 24c so as to reduce the residual stress described above (e.g., to mutually cancel the stress of the chip A1 and the stress of the chip A2).

### 1-2. Semiconductor Device Manufacturing Method

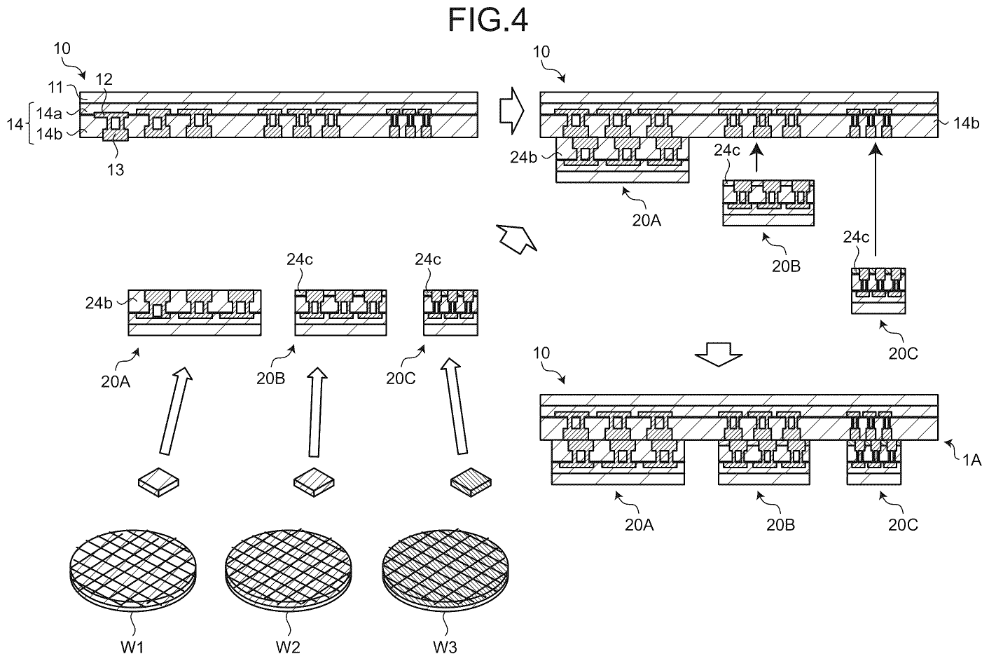

A method for manufacturing the semiconductor device 1A according to the present embodiment will be described with reference to FIG. 4. FIG. 4 is a diagram illustrating a manufacturing process of the semiconductor device 1A according to the present embodiment.

As illustrated in FIG. 4, the semiconductor substrate 10 is prepared, and the first semiconductor element 20A, the second semiconductor element 20B, and the third semiconductor element 20C are prepared. The semiconductor substrate 10 is, for example, a wafer, and is formed based on a normal manufacturing process. The example in FIG. 4 is a part of the wafer that is the semiconductor substrate 10. In addition, the first semiconductor element 20A is cut out from a wafer W1 and divided into individual pieces, the second semiconductor element 20B is cut out from a wafer W2 and divided into individual pieces, and the third semiconductor element 20C is cut out from a wafer W3 and divided into individual pieces.

The first semiconductor element 20A, the second semiconductor element 20B, and the third semiconductor element 20C are bonded to the semiconductor substrate 10 by a chip on wafer (CoW) technique (CoW bonding). Thus, the semiconductor device 1A is completed. Specifically, a plurality of first semiconductor elements 20A, a plurality of second semiconductor elements 20B, and a plurality of third semiconductor elements 20C are bonded onto a wafer that is the semiconductor substrate 10, and the wafer is cut and divided into a plurality of semiconductor devices 1A. Note that before or after dividing the semiconductor device 1A into individual pieces, necessary members are provided in the semiconductor device 1A to complete, for example, a solid-state imaging device, a light emitting device, a storage device, or the like. As an example, in the solid-state imaging device, necessary members such as an on-chip lens, an on-chip color filter, and a support substrate are provided in the semiconductor device 1A. Bonding between the terminals 13 of the semiconductor substrate 10 and the terminals 23 of the semiconductor elements 20 (20A, 20B, 20C) is realized, for example, by thermal diffusion bonding of Cu—Cu.

In the above-described CoW bonding, the second semiconductor element 20B and the third semiconductor element 20C are bonded to the semiconductor substrate 10 by different materials. Specifically, the respective insulating layers 24c of the second semiconductor element 20B and the third semiconductor element 20C are bonded to the insulating layer 14b of the semiconductor substrate 10. These insulating layer 24c and insulating layer 14b are formed of different materials. As a result, as compared with a case where the insulating layer 24c and the insulating layer 14b are formed of the same material, as is in the normal case, it is possible to improve the bonding strength, and further, it is possible to improve the withstand voltage and suppress distortion. For example, the material of the insulating layer 24c can be appropriately changed according to necessary bonding strength, necessary withstand voltage, allowable distortion, and the like.

### 1-3. Semiconductor Element Manufacturing Method

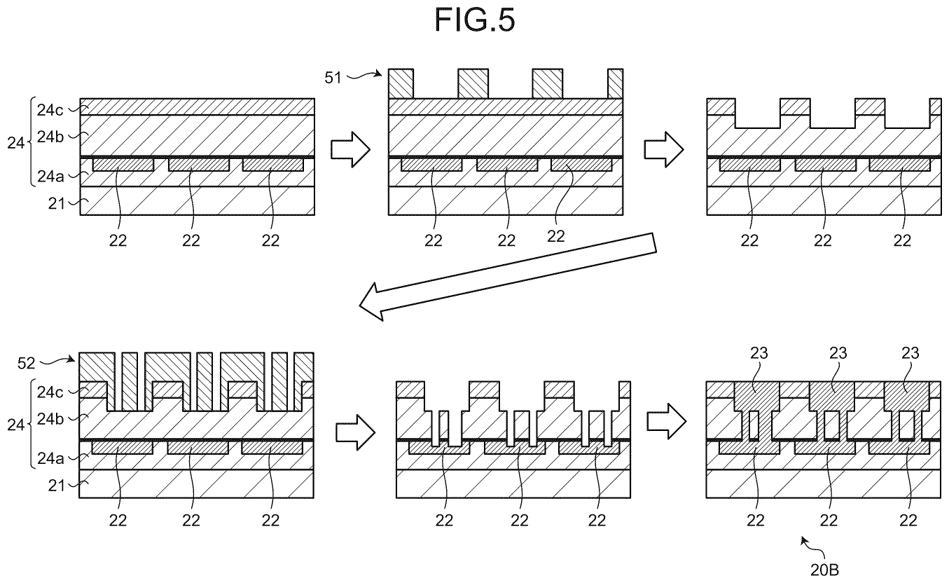

A manufacturing process of the above-described second semiconductor element 20B, i.e., the wafer W2 including the plurality of second semiconductor elements 20B, will be described with reference to FIG. 5. FIG. 5 is a diagram illustrating a manufacturing process of the second semiconductor element 20B according to the present embodiment. In an example in FIG. 5, one second semiconductor element 20B is illustrated. Since the manufacturing process of the third semiconductor element 20C is similar to the manufacturing process of the second semiconductor element 20B, the description thereof will be omitted.

As illustrated in FIG. 5, the insulating layer 24a is laminated on the substrate 21, and the plurality of circuit elements 22 is provided on the insulating layer 24a. Next, the insulating layer 24b is laminated on the insulating layer 24a and the plurality of circuit elements 22, and the insulating layer 24c is laminated on the insulating layer 24b. Next, a photoresist layer (mask layer) 51 is laminated on the insulating layer 24c by lithography, and the insulating layer 24c and the insulating layer 24b are processed by dry etching. Then, a photoresist layer (mask layer) 52 is laminated on the insulating layer 24c and the insulating layer 24b by lithography, the insulating layer 24b and a part of each of the plurality of circuit elements 22 are processed by dry etching. Finally, these processed portions are filled with metal to form the terminals 23. In this way, the wafer W2 including the plurality of second semiconductor elements 20B is completed, and the second semiconductor elements 20B are cut out from the wafer W2. Thus, the second semiconductor element 20B is completed.

### 2. Second Embodiment

### 2-1. Configuration Example of Semiconductor Device

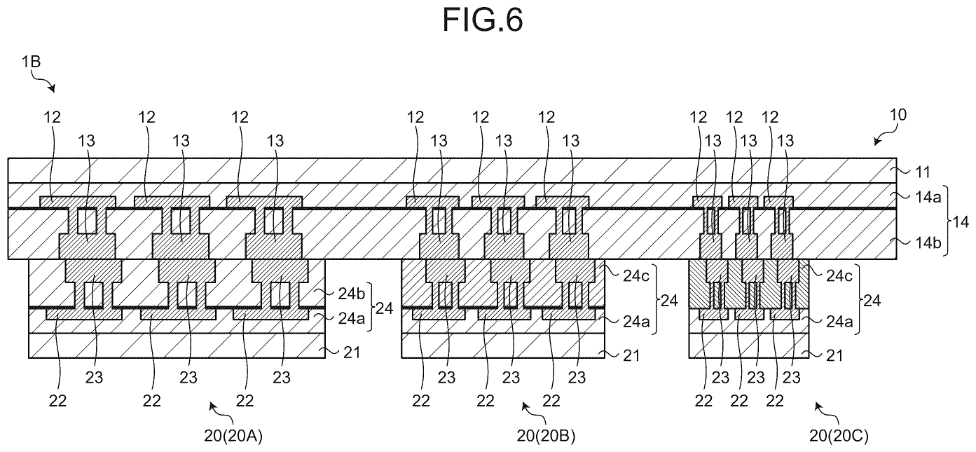

A configuration example of a semiconductor device 1B according to the present embodiment will be described with reference to FIG. 6. FIG. 6 is a cross-sectional view illustrating the configuration example of the semiconductor device 1B according to the present embodiment. In the present embodiment, parts basically different from those of the first embodiment will be described.

As illustrated in FIG. 6, in the semiconductor device 1B according to the present embodiment, the configurations of a second semiconductor element 20B and a third semiconductor element 20C are different from those of the first embodiment. In the second semiconductor element 20B and the third semiconductor element 20C according to the present embodiment, the insulating layer 24 includes two insulating layers 24a and 24c. For example, by increasing the thickness of the insulating layer (third insulating layer) 24c as compared with the first embodiment, it is possible to reliably suppress distortion caused by the CTE described above. Usually, since the plane size of the semiconductor element 20 is determined by standards or the like, it is difficult to change the size, but the thickness of the insulating layer 24c can be relatively freely changed. Therefore, the thickness of the insulating layer 24c can be appropriately adjusted to reliably suppress distortion caused by the CTE described above.

### 2-2. Semiconductor Device Manufacturing Method

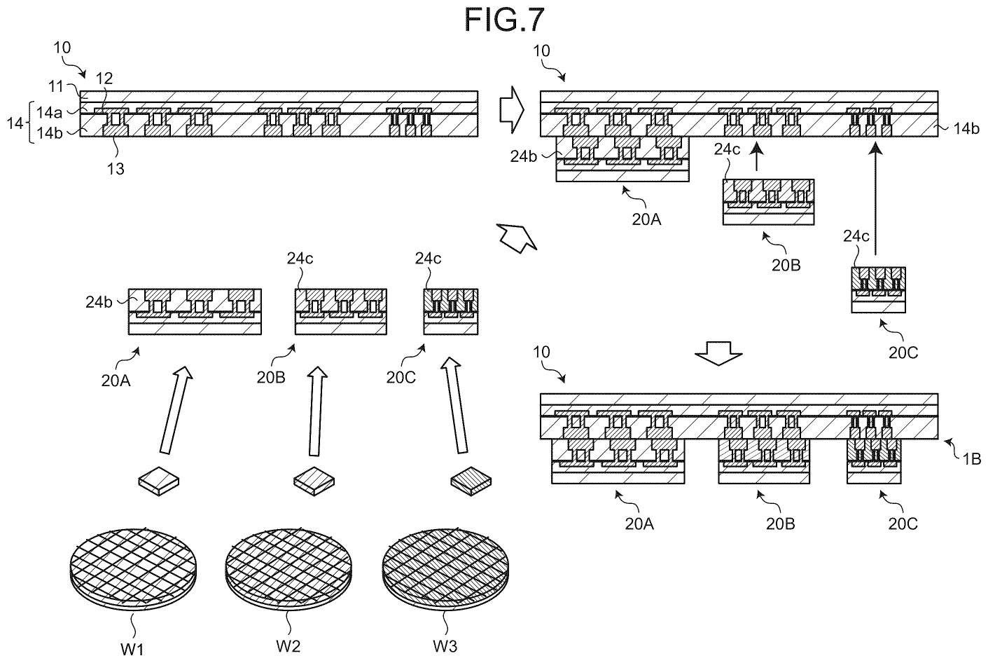

A method for manufacturing the semiconductor device 1B according to the present embodiment will be described with reference to FIG. 7. FIG. 7 is a diagram illustrating a manufacturing process of the semiconductor device 1B according to the present embodiment.

As illustrated in FIG. 7, similarly to the first embodiment, a semiconductor substrate 10 is prepared, and the first semiconductor element 20A, the second semiconductor element 20B, and the third semiconductor element 20C are prepared. The semiconductor substrate 10 is, for example, a wafer, and is formed based on a normal manufacturing process. In the example in FIG. 7, a part of the wafer that is the semiconductor substrate 10 is illustrated. In addition, the first semiconductor element 20A is cut out from a wafer W1 and divided into individual pieces, the second semiconductor element 20B is cut out from a wafer W2 and divided into individual pieces, and the third semiconductor element 20C is cut out from a wafer W3 and divided into individual pieces.

The first semiconductor element 20A, the second semiconductor element 20B, and the third semiconductor element 20C are bonded to the semiconductor substrate 10 by the CoW technology (CoW bonding) as in the first embodiment. Thus, the semiconductor device 1B is completed. Specifically, a plurality of the first semiconductor elements 20A, a plurality of the second semiconductor elements 20B, and a plurality of the third semiconductor elements 20C are bonded onto a wafer that is the semiconductor substrate 10, and the wafer is cut and divided into a plurality of semiconductor devices 1B. Note that before or after dividing the semiconductor device 1B into individual pieces, necessary members are provided in the semiconductor device 1B to complete, for example, a solid-state imaging device, a light emitting device, a storage device, or the like.

In the above-described CoW bonding, as in the first embodiment, the second semiconductor element 20B and the third semiconductor element 20C are bonded to the semiconductor substrate 10 by different materials. Specifically, the respective insulating layers 24c of the second semiconductor element 20B and the third semiconductor element 20C are bonded to the insulating layer 14b of the semiconductor substrate 10. These insulating layer 24c and insulating layer 14b are formed of different materials. As a result, as compared with a case where the insulating layer 24c and the insulating layer 14b are formed of the same material, as is in the normal case, it is possible to improve the bonding strength, and further, it is possible to improve the withstand voltage and suppress distortion. For example, the material of the insulating layer 24c can be appropriately changed according to necessary bonding strength, necessary withstand voltage, allowable distortion, and the like.

### 2-3. Semiconductor Element Manufacturing Method

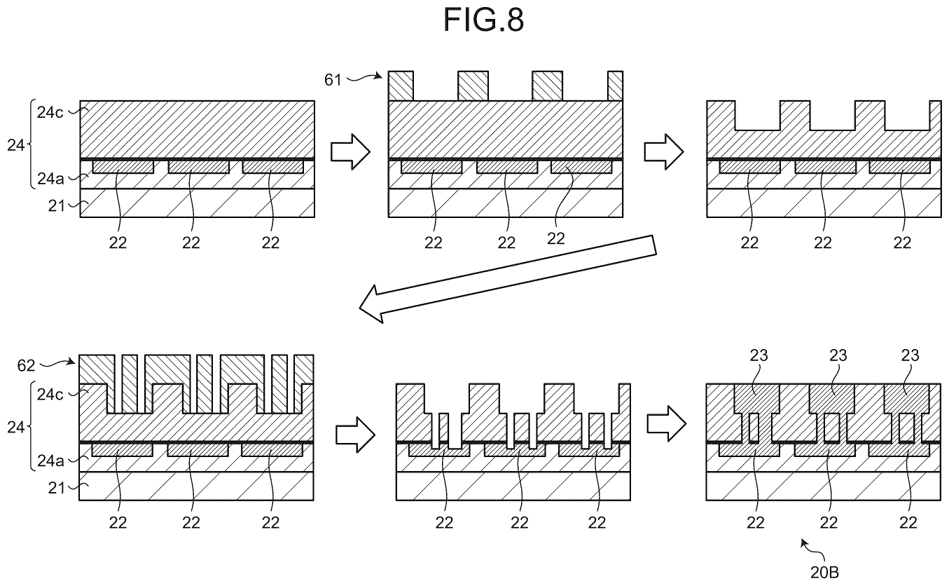

A manufacturing process of the above-described second semiconductor element 20B, i.e., the wafer W2 including the plurality of second semiconductor elements 20B will be described with reference to FIG. 8. FIG. 8 is a diagram illustrating the manufacturing process of the second semiconductor element 20B according to the present embodiment. In the example in FIG. 8, one second semiconductor element 20B is illustrated. Since the manufacturing process of the third semiconductor element 20C is similar to the manufacturing process of the second semiconductor element 20B, the description thereof will be omitted.

As illustrated in FIG. 8, the insulating layer 24a is laminated on a substrate 21, a plurality of circuit elements 22 is provided on the insulating layer 24a, and the insulating layer 24c is laminated on the insulating layer 24a and the circuit elements 22. Next, a photoresist layer (mask layer) 61 is laminated on the insulating layer 24c by lithography, and the insulating layer 24c is processed by dry etching. Next, a photoresist layer (mask layer) 62 is laminated on the insulating layer 24c by lithography, and the insulating layer 24c and a part of each of the circuit elements 22 are processed by dry etching. Finally, these processed portions are filled with metal to form the terminals 23. In this way, the wafer W2 including the plurality of second semiconductor elements 20B is completed, and the second semiconductor elements 20B are cut out from the wafer W2. Thus, the second semiconductor element 20B is completed.

### 3. Third Embodiment

### 3-1. Configuration Example of Semiconductor Device

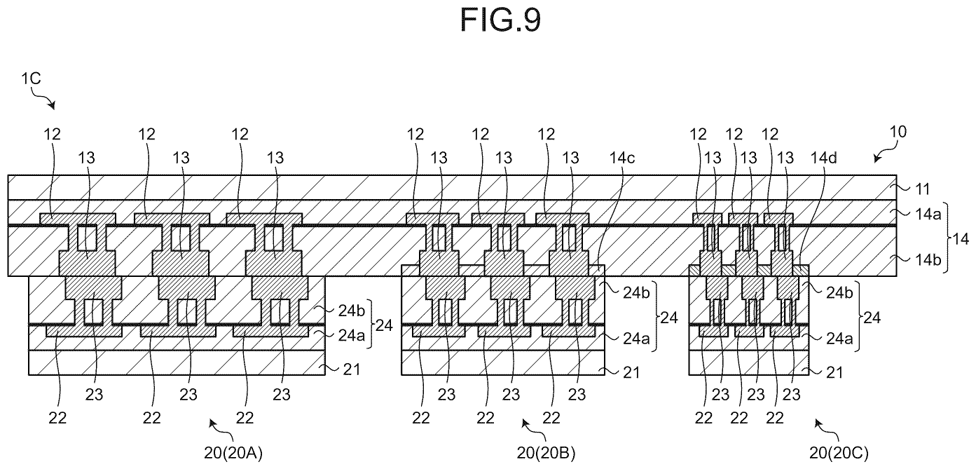

A configuration example of a semiconductor device 1C according to the present embodiment will be described with reference to FIG. 9. FIG. 9 is a cross-sectional view illustrating a configuration example of a semiconductor device 1C according to the present embodiment. In the present embodiment, parts basically different from those of the first embodiment will be described.

As illustrated in FIG. 9, in the semiconductor device 1C according to the present embodiment, configurations of a semiconductor substrate 10, a second semiconductor element 20B, and a third semiconductor element 20C are different from those of the first embodiment. The semiconductor substrate 10 according to the present embodiment includes two insulating layers (third insulating layers) 14c and 14d. These insulating layers 14c and 14d are formed of a material different from the insulating layers 14a and 14b, and are formed of, for example, the same material as the insulating layer 24c according to the first embodiment. In addition, the second semiconductor element 20B and the third semiconductor element 20C according to the present embodiment have the same configuration as the first semiconductor element 20A according to the first embodiment, and the insulating layer 24 includes two insulating layers 24a and 24b.

### 3-2. Semiconductor Device Manufacturing Method

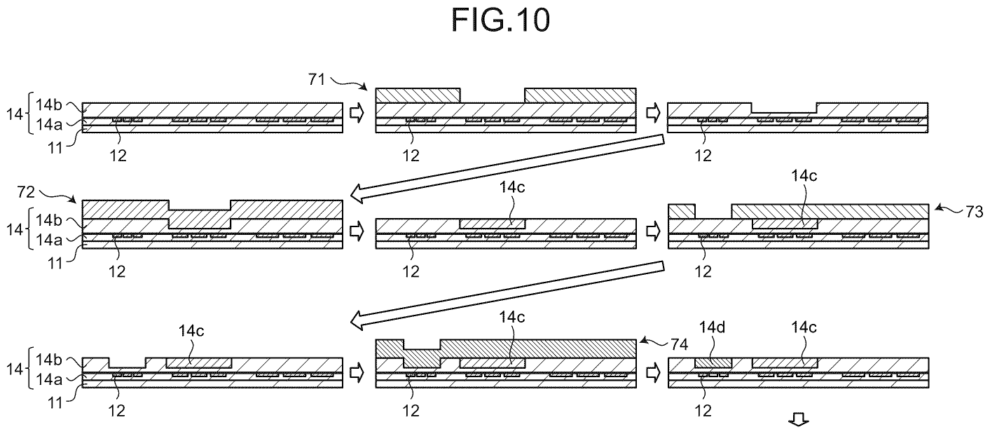

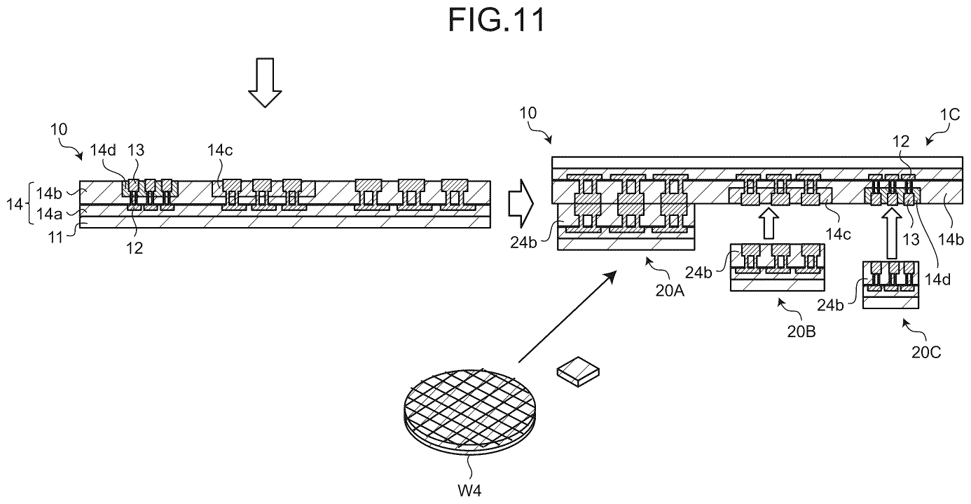

A method for manufacturing the semiconductor device 1C according to the present embodiment will be described with reference to FIGS. 10 and 11. FIGS. 10 and 11 are diagrams illustrating a manufacturing process of the semiconductor device 1C according to the present embodiment.

As illustrated in FIG. 10, the insulating layer 14a is laminated on a substrate 11, a plurality of circuit elements 12 is provided on the insulating layer 24a, and the insulating layer 14b is laminated on the insulating layer 14a and the circuit elements 12. Next, a photoresist layer (mask layer) 71 is laminated on the insulating layer 14b by lithography, and the insulating layer 14b is processed by dry etching. This processing position is a position where the insulating layer 14c is provided. Next, a material (e.g., SiCN) 72 for forming the insulating layer 14c is laminated (deposited) on the insulating layer 14b, and planarization is performed by a chemical mechanical polishing (CMP) technique. Then, a photoresist layer (mask layer) 73 is laminated on the insulating layer 14b and the insulating layer 14c by lithography, and the insulating layer 14b is processed by dry etching. This processing position is a position where the insulating layer 14d is provided. Next, a material (e.g., SiN) 74 for forming the insulating layer 14d is laminated (deposited) on the insulating layer 14b, and planarization is performed by the CMP technique. Next, as illustrated in FIG. 11, the terminals 13 are formed by processing. Thus, the semiconductor substrate 10 including the two insulating layers 14c and 14d is completed.

In this way, the semiconductor substrate 10 is prepared. The semiconductor substrate 10 is, for example, a wafer, and in the example in FIGS. 10 and 11, a part of the wafer that is the semiconductor substrate 10 is illustrated. The first semiconductor element 20A, the second semiconductor element 20B, and the third semiconductor element 20C are also prepared. The first semiconductor element 20A, the second semiconductor element 20B, and the third semiconductor element 20C may be cut out from the same wafer W4 and divided into individual pieces, or may be cut out from a plurality of different wafers W4 and divided into individual pieces.

The first semiconductor element 20A, the second semiconductor element 20B, and the third semiconductor element 20C are bonded to the semiconductor substrate 10 by the CoW technology (CoW bonding) as in the first embodiment. Thus, the semiconductor device 1C is completed. Specifically, a plurality of the first semiconductor elements 20A, a plurality of the second semiconductor elements 20B, and a plurality of the third semiconductor elements 20C are bonded onto the wafer that is the semiconductor substrate 10, and the wafer is cut and divided into a plurality of the semiconductor devices 1C. Note that before or after dividing the semiconductor device 1C into individual pieces, necessary members are provided in the semiconductor device 1C to complete, for example, a solid-state imaging device, a light emitting device, a storage device, or the like.

In the above-described CoW bonding, similarly to the first embodiment, the semiconductor substrate 10, the second semiconductor element 20B, and the third semiconductor element 20C are bonded by different materials. Specifically, the insulating layer 14c of the semiconductor substrate 10 and the insulating layer 24b of the second semiconductor element 20B are bonded, and the insulating layer 14d of the semiconductor substrate 10 and the insulating layer 24b of the third semiconductor element 20C are bonded. These insulating layers 14c and 14d and the insulating layer 24b are formed of different materials. As a result, as compared with a case where the insulating layers 14c and 14d are formed of the same material as the insulating layer 24b, as in the normal case, it is possible to improve the bonding strength, and further, it is possible to improve the withstand voltage and suppress distortion. For example, the material of the insulating layers 14c and 14d can be appropriately changed according to necessary bonding strength, necessary withstand voltage, allowable distortion, and the like.

### 4. Fourth Embodiment

### 4-1. Configuration Example of Semiconductor Device

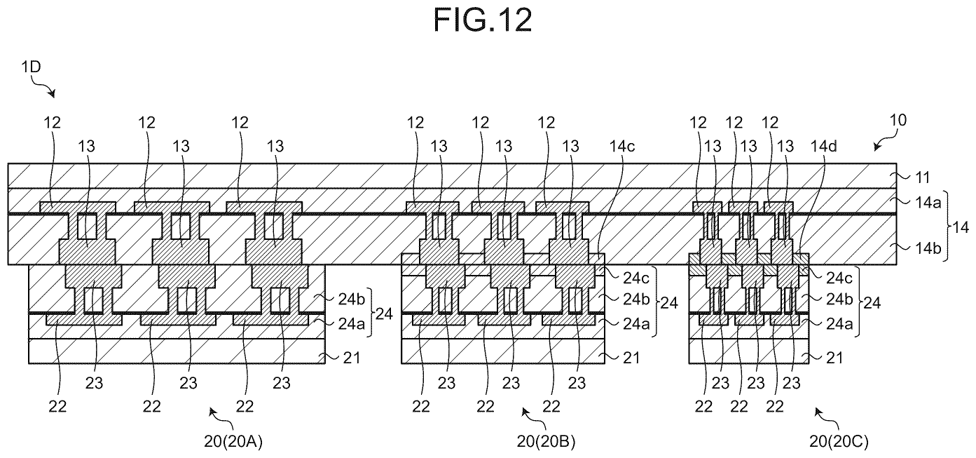

A configuration example of a semiconductor device 1D according to the present embodiment will be described with reference to FIG. 12. FIG. 12 is a cross-sectional view illustrating the configuration example of the semiconductor device 1D according to the present embodiment. In the present embodiment, parts basically different from those of the third embodiment will be described.

As illustrated in FIG. 12, in the semiconductor device 1D according to the present embodiment, a configurations of a second semiconductor element 20B and a third semiconductor element 20C are different from those of the third embodiment. Configurations of the second semiconductor element 20B and the third semiconductor element 20C according to the present embodiment are the same as those of the first embodiment.

### 4-2. Semiconductor Device Manufacturing Method

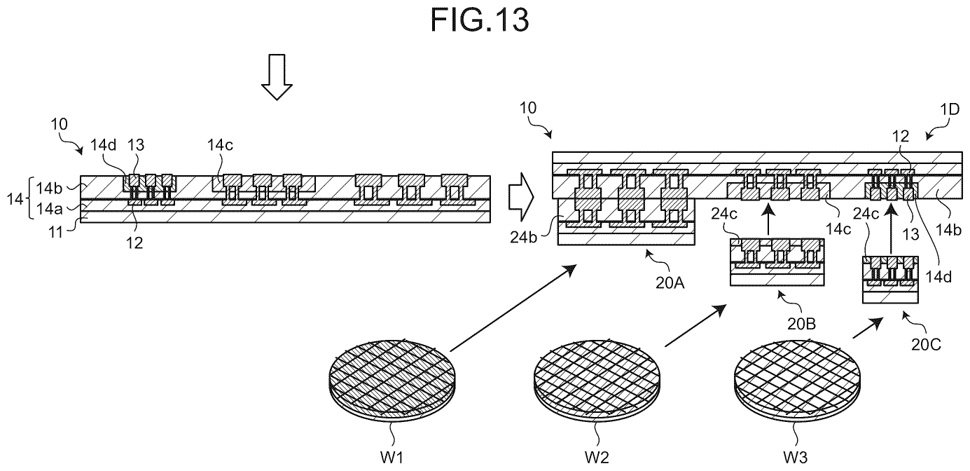

A method for manufacturing the semiconductor device 1D according to the present embodiment will be described with reference to FIG. 13. FIG. 13 is a diagram illustrating a manufacturing process of the semiconductor device 1D according to the present embodiment.

As illustrated in FIG. 13, the semiconductor substrate 10 according to the third embodiment is prepared (the manufacturing process of the semiconductor substrate 10 is the same as that of the third embodiment). The semiconductor substrate 10 is, for example, a wafer, and in the example in FIG. 13, a part of the wafer that is the semiconductor substrate 10 is illustrated. In addition, the first semiconductor element 20A, the second semiconductor element 20B, and the third semiconductor element 20C according to the first embodiment are prepared. The first semiconductor element 20A is cut out from the wafer W1 and divided into individual pieces, the second semiconductor element 20B is cut out from the wafer W2 and divided into individual pieces, and the third semiconductor element 20C is cut out from the wafer W3 and divided into individual pieces.

The first semiconductor element 20A, the second semiconductor element 20B, and the third semiconductor element 20C are bonded to the semiconductor substrate 10 by the CoW technology (CoW bonding) as in the first embodiment. Thus, the semiconductor device 1D is completed. Specifically, a plurality of first semiconductor elements 20A, a plurality of second semiconductor elements 20B, and a plurality of third semiconductor elements 20C are bonded onto a wafer that is the semiconductor substrate 10, and the wafer is cut and divided into a plurality of semiconductor devices 1D. Note that before or after dividing the semiconductor device 1D into individual pieces, members necessary for the semiconductor device 1D are provided to complete, for example, a solid-state imaging device, a light emitting device, a storage device, or the like.

In the above-described CoW bonding, the semiconductor substrate 10, the second semiconductor element 20B, and the third semiconductor element 20C are bonded to each other by a material different from the insulating layers 14a, 14b, 24a, and 24b. Specifically, the insulating layer 14c of the semiconductor substrate 10 and the insulating layer 24c of the second semiconductor element 20B are bonded, and the insulating layer 14d of the semiconductor substrate 10 and the insulating layer 24c of the third semiconductor element 20C are bonded. These insulating layers 14c, 14d, and 24c are formed of a material different from that of the insulating layers 14a, 14b, 24a, and 24b. As a result, as compared with a case where the insulating layers 14c, 14d, and 24c are formed of the same material as the insulating layers 14a, 14b, 24a, and 24b, as is the normal case, it is possible to improve the bonding strength, and further, it is possible to improve the withstand voltage and suppress distortion. For example, the material of the insulating layer 24c can be appropriately changed according to necessary bonding strength, necessary withstand voltage, allowable distortion, and the like. The materials of the insulating layers 14c, 14d, and 24c may be the same or different.

### 5. Fifth Embodiment

### 5-1. Configuration Example of Semiconductor Device

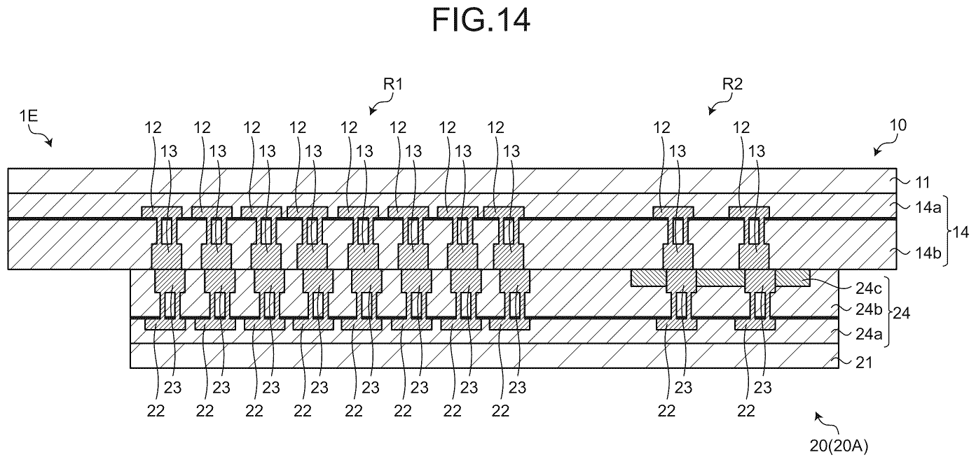

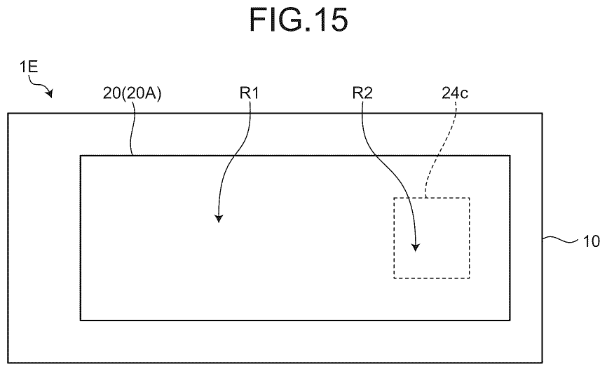

A configuration example of a semiconductor device 1E according to the present embodiment will be described with reference to FIGS. 14 and 15. FIG. 14 is a cross-sectional view illustrating the configuration example of the semiconductor device 1E according to the present embodiment. FIG. 15 is a plan view illustrating the configuration example of the semiconductor device 1E according to the present embodiment. In the present embodiment, parts basically different from those of the first embodiment will be described.

As illustrated in FIGS. 14 and 15, in the semiconductor device 1E according to the present embodiment, a configuration of a first semiconductor element 20A is different from that of the first embodiment. The semiconductor device 1E does not include the second semiconductor element 20B and the third semiconductor element 20C according to the first embodiment.

The first semiconductor element 20A according to the present embodiment has a dense region R1 in which a pitch of the terminals 23 is narrow and a sparse region R2 in which a pitch of the terminals 23 is wide. In the example in FIG. 1, in a surface direction of the semiconductor substrate 10, a left side region is the dense region R1 where the pitch of the terminals 23 is narrow, and a right region is the sparse region R2 where the pitch of the terminals 23 is wide. For example, the terminals 23 in the left region are provided at a first pitch, and the terminals 23 in the right region are provided at a second pitch wider than the first pitch.

In addition, the first semiconductor element 20A according to the present embodiment includes the insulating layer 24c according to the first embodiment. The insulating layer 24c is provided in the sparse region R2 where the pitch of the terminals 23 is wide. The insulating layer 24c is located on a surface of the insulating layer 24 on a side of the semiconductor substrate 10 and functions as a bonding layer for bonding the semiconductor substrate 10 and the first semiconductor element 20A.

Note that the insulating layer 24c is provided only in the sparse region R2, but is not limited thereto. For example, the insulating layer 24c may be provided only in the dense region R1, or may be provided in both the sparse region R2 and the dense region R1. In addition, although the insulating layer 24c is provided only on the first semiconductor element 20A, for example, the insulating layer 24c may be provided only on the semiconductor substrate 10 on a side facing the sparse region R2 of the first semiconductor element 20A, or may be provided on both the first semiconductor element 20A and the semiconductor substrate 10.

### 5-2. Semiconductor Device Manufacturing Method

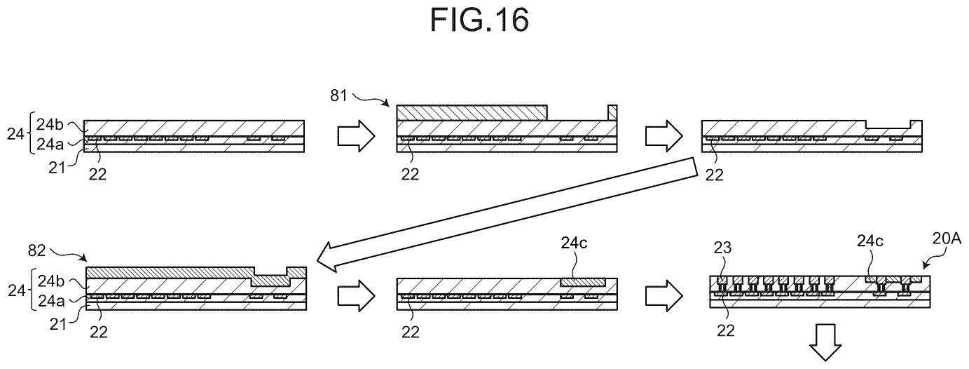

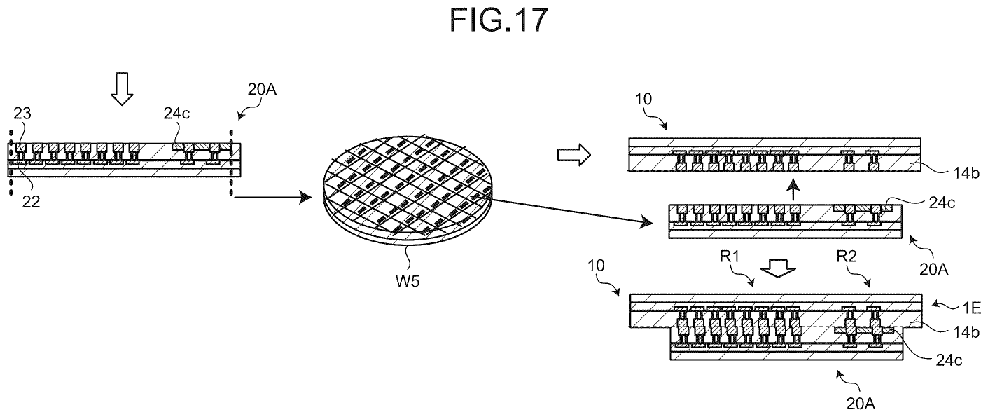

A method for manufacturing the semiconductor device 1E according to the present embodiment will be described with reference to FIGS. 16 and 17. FIGS. 16 and 17 are diagrams illustrating a manufacturing process of the semiconductor device 1E according to the present embodiment.

As illustrated in FIG. 16, the insulating layer 24a is laminated on the substrate 21, a plurality of circuit elements 22 is provided, and the insulating layer 24b is laminated on the insulating layer 24a and the circuit elements 22. Next, a photoresist layer (mask layer) 81 is laminated on the insulating layer 24b by lithography, and the insulating layer 24b is processed by dry etching. This processing position is a position where the insulating layer 24c is provided. Next, a material (e.g., SiN) 82 for forming the insulating layer 24c is laminated (deposited) on the insulating layer 24b, and planarization is performed by the CMP technique. Then, the terminals 13 are formed by processing. Thus, the first semiconductor element 20A including the insulating layer 24c is completed.

In this way, the first semiconductor element 20A is prepared. Specifically, as illustrated in FIG. 17, a wafer W5 having a plurality of the first semiconductor elements 20A is prepared, and the plurality of first semiconductor elements 20A is cut out from the wafer W5 and divided into individual pieces to prepare the first semiconductor elements 20A. In addition, the semiconductor substrate 10 is also prepared. The semiconductor substrate 10 is, for example, a wafer, and is formed based on a normal manufacturing process. In the example in FIG. 17, a part of the wafer that is the semiconductor substrate 10 is illustrated.

The first semiconductor element 20A is bonded to the semiconductor substrate 10 by the CoW technology (CoW bonding). Thus, the semiconductor device 1E is completed. Specifically, the plurality of first semiconductor elements 20A is bonded onto the wafer that is the semiconductor substrate 10, and the wafer is cut and divided into a plurality of the semiconductor devices 1E. Note that before or after dividing the semiconductor device 1E into individual pieces, necessary members are provided in the semiconductor device 1E to complete, for example, a solid-state imaging device, a light emitting device, a storage device, or the like.

In the above-described CoW bonding, the semiconductor substrate 10 and the sparse region R2 of the first semiconductor element 20A are bonded by different materials. Specifically, the insulating layer 14b of the semiconductor substrate 10 and the insulating layer 24c of the first semiconductor element 20A are bonded. These insulating layer 14b and insulating layer 24c are made of different materials. As a result, as compared with a case where the insulating layer 14b and the insulating layer 24c are formed of the same material, as in the normal case, it is possible to improve the bonding strength, and further, it is possible to improve the withstand voltage and suppress distortion. For example, the material of the insulating layer 24c can be appropriately changed according to necessary bonding strength, necessary withstand voltage, allowable distortion, and the like.

### 6. Sixth Embodiment

### 6-1. Configuration Example of Semiconductor Device

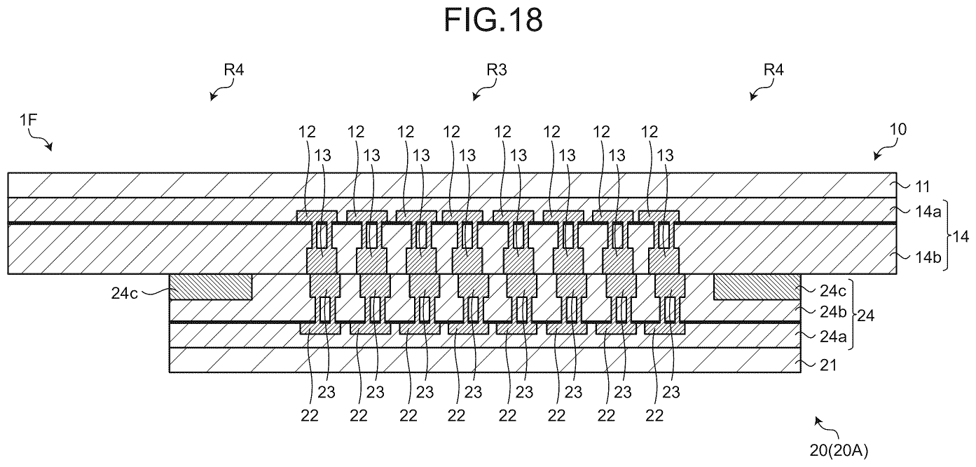

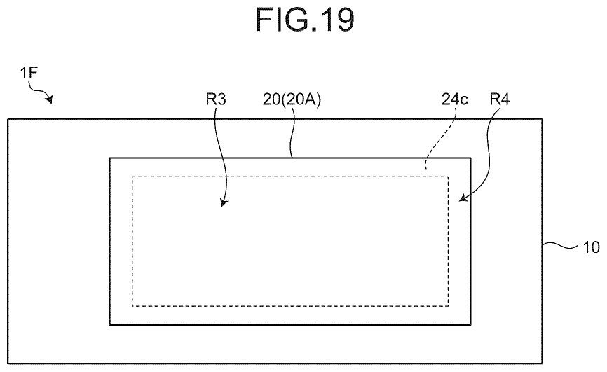

A configuration example of a semiconductor device 1F according to the present embodiment will be described with reference to FIGS. 18 and 19. FIG. 18 is a cross-sectional view illustrating the configuration example of the semiconductor device 1F according to the present embodiment. FIG. 19 is a plan view illustrating the configuration example of the semiconductor device 1F according to the present embodiment. In the present embodiment, parts basically different from those of the first embodiment will be described.

As illustrated in FIGS. 18 and 19, in the semiconductor device 1F according to the present embodiment, a configuration of a first semiconductor element 20A is different from that of the first embodiment. The semiconductor device 1F does not include the second semiconductor element 20B and the third semiconductor element 20C according to the first embodiment.

The first semiconductor element 20A according to the present embodiment has the terminals 23 according to the first embodiment in a central region R3, and has the insulating layer 24c according to the first embodiment in an outer peripheral region R4. As illustrated in FIG. 19, the insulating layer 24c is formed in a rectangular annular shape in the outer peripheral region R4 on a surface of the first semiconductor element 20A on a side of the semiconductor substrate 10. The insulating layer 24c is located on a surface of the insulating layer 24 on a side of the semiconductor substrate 10 and functions as a bonding layer for bonding the semiconductor substrate 10 and the first semiconductor element 20A.

The insulating layer 24c is continuously provided in the rectangular annular shape in the outer peripheral region R4, but is not limited thereto. For example, the insulating layer 24c may be provided in a dotted shape so as not to be continuous, or may be provided in another shape. The insulating layer 24c in the annular shape is provided only on the first semiconductor element 20A. However, for example, the insulating layer 24c may be provided only on the semiconductor substrate 10 on a side facing the outer peripheral region R4 of the first semiconductor element 20A, or may be provided on both the first semiconductor element 20A and the semiconductor substrate 10.

### 6-2. Semiconductor Device Manufacturing Method

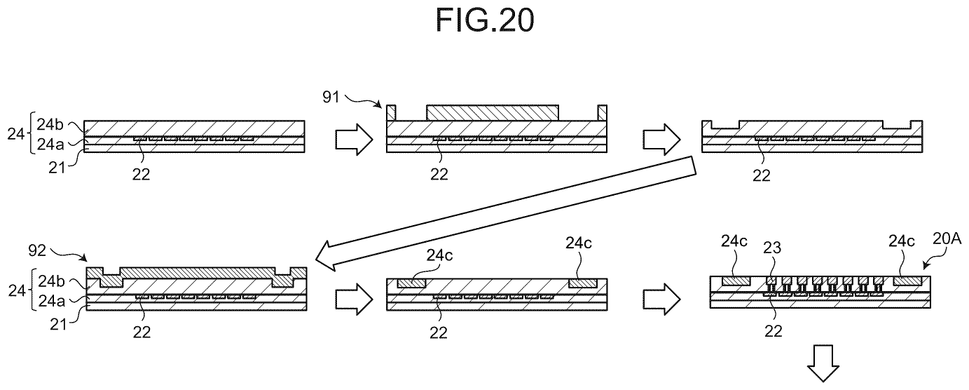

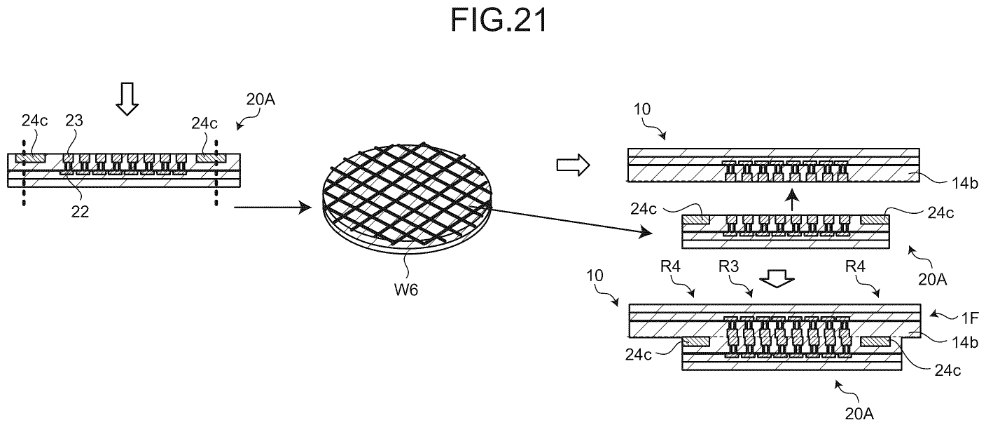

A method for manufacturing the semiconductor device 1F according to the present embodiment will be described with reference to FIGS. 20 and 21. FIGS. 20 and 21 are diagrams illustrating a manufacturing process of the semiconductor device 1F according to the present embodiment.

As illustrated in FIG. 20, the insulating layer 24a is laminated on the substrate 21, a plurality of circuit elements 22 is provided, and the insulating layer 24b is laminated on the insulating layer 24a and the circuit elements 22. Next, a photoresist layer (mask layer) 91 is laminated on the insulating layer 24b by lithography, and the insulating layer 24b is processed by dry etching. This processing position is a position where the insulating layer 24c is provided. Next, a material (e.g., SiN) for forming the insulating layer 24c is laminated (deposited) on the insulating layer 24b, and planarization is performed by the CMP technique. Then, the terminals 13 are formed by processing. Thus, the first semiconductor element 20A including the insulating layer 24c is completed.

In this way, the first semiconductor element 20A is prepared. Specifically, as illustrated in FIG. 21, a wafer W6 having a plurality of the first semiconductor elements 20A is prepared, and the plurality of first semiconductor elements 20A is cut out from the wafer W6 and divided into individual pieces to prepare the first semiconductor elements 20A. In addition, the semiconductor substrate 10 is also prepared. The semiconductor substrate 10 is, for example, a wafer, and is formed based on a normal manufacturing process. In the example in FIG. 21, a part of the wafer that is the semiconductor substrate 10 is illustrated.

The first semiconductor element 20A is bonded to the semiconductor substrate 10 by the CoW technology (CoW bonding). Thus, the semiconductor device 1F is completed. Specifically, the plurality of first semiconductor elements 20A is bonded onto the wafer that is the semiconductor substrate 10, and the wafer is cut and divided into a plurality of semiconductor devices 1F. Note that before or after dividing the semiconductor device 1F into individual pieces, necessary members are provided in the semiconductor device 1F to complete, for example, a solid-state imaging device, a light emitting device, a storage device, or the like.

In the above-described CoW bonding, the semiconductor substrate 10 and the outer peripheral region R4 of the first semiconductor element 20A are bonded by different materials. Specifically, the insulating layer 14b of the semiconductor substrate 10 and the insulating layer 24c of the first semiconductor element 20A are bonded. These insulating layer 14b and insulating layer 24c are made of different materials. As a result, as compared with a case where the insulating layer 14b and the insulating layer 24c are formed of the same material, as in the normal case, it is possible to improve the bonding strength, and further, it is possible to improve the withstand voltage and suppress distortion. For example, the material of the insulating layer 24c can be appropriately changed according to necessary bonding strength, necessary withstand voltage, allowable distortion, and the like.

### 7. Seventh Embodiment

### 7-1. Configuration Example of Semiconductor Device

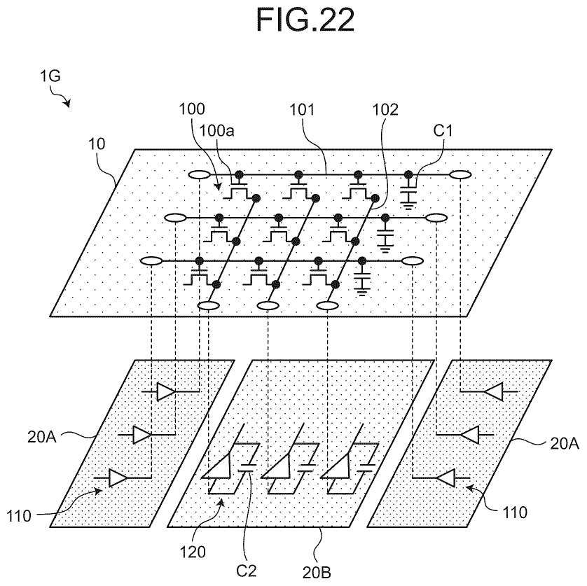

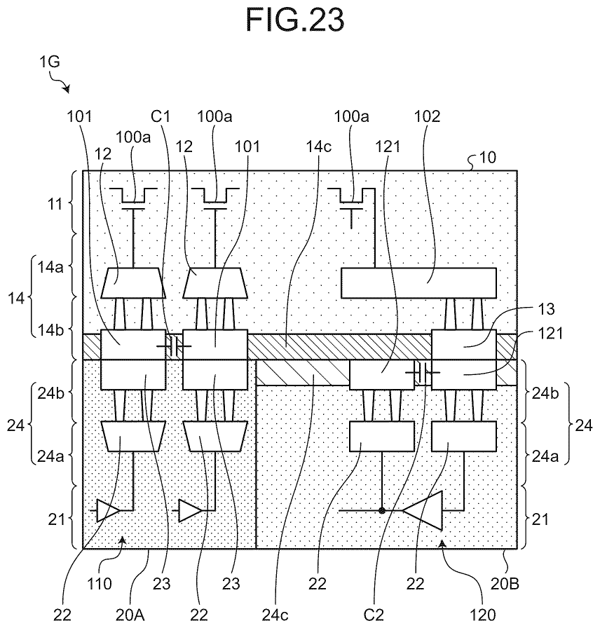

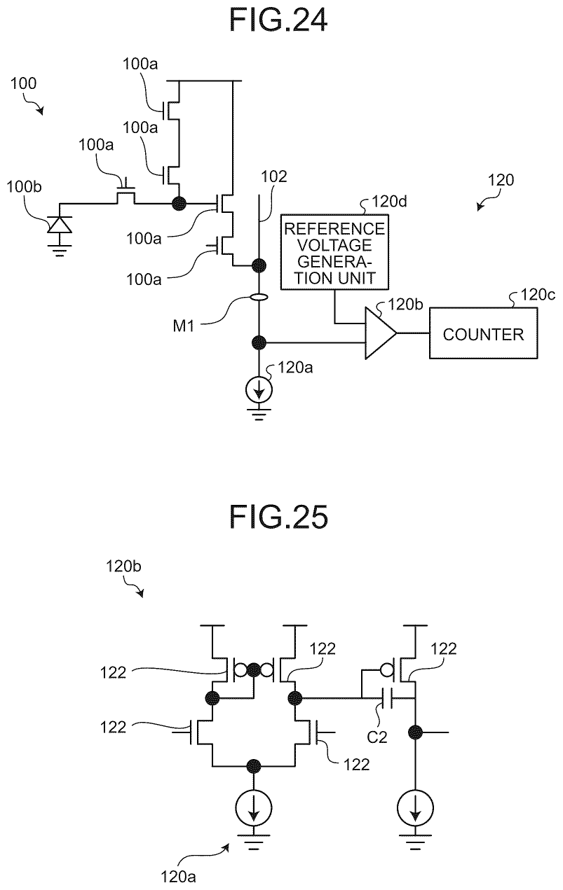

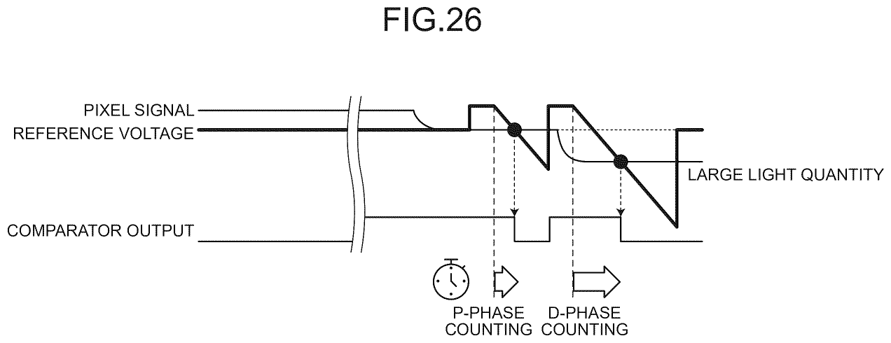

A configuration example of a semiconductor device 1G according to the present embodiment will be described with reference to FIGS. 22 to 26. FIG. 22 is a perspective view illustrating the configuration example of the semiconductor device 1G according to the present embodiment. FIG. 23 is a cross-sectional view illustrating the configuration example of the semiconductor device 1G according to the present embodiment. FIG. 24 is a diagram illustrating a circuit example of the semiconductor device 1G according to the present embodiment. FIG. 25 is a diagram illustrating a circuit example of a comparator 72 according to the present embodiment. FIG. 26 is a diagram illustrating an output example of the comparator 72 according to the present embodiment. In the present embodiment, parts basically different from those of the fourth embodiment will be described.

As illustrated in FIG. 22, in the semiconductor device 1G according to the present embodiment, for example, the semiconductor substrate 10 is a pixel chip including a plurality of pixels 100. Each of two semiconductor elements 20A is a circuit chip including a plurality of drivers 110. A semiconductor element 20B is a circuit chip including an analog to digital converter (ADC) 120. These pixel chip, circuit chip, and the like may include other elements, circuits, and the like.

Each of the pixels 100 of the semiconductor substrate 10 includes, for example, a transistor 100a and a photodiode (details will be described later). A horizontal signal line (drive wiring) 101 and a vertical signal line 102 are connected to each of the pixels 100. The horizontal signal line 101 is arranged, for example, in each row of a two-dimensional matrix, and is commonly connected to the plurality of pixels 100 arranged in one row. The vertical signal line 102 is arranged, for example, in each column of the two-dimensional matrix, and is commonly connected to the plurality of pixels 100 arranged in one column. The pixel 100 is controlled by a control signal transmitted by the horizontal signal line 101 to generate an image signal, and outputs the generated image signal to the ADC 120 or the like of the semiconductor element 20B via the vertical signal line 102.

Here, for example, there is a layout method in which a wiring layer (e.g., layer including the insulating layer 14c and the insulating layer 24c (FIG. 23)) used at a bonding interface between the semiconductor substrate 10 and the semiconductor elements 20A and 20B is used, and the wiring layer is used as a circuit wiring node instead of electrical bonding between chips. When this method is used, depending on the wiring (wiring node), there is a wiring whose parasitic capacitance is desired to be reduced, such as a drive wiring, and there is also a wiring whose capacitance is desired to be increased as much as possible, such as a phase compensation capacitance and a charge holding capacitance (in-pixel capacitance). For example, since a coupling capacitance between wiring layers (e.g., between Cu wiring layers) contributes to the above capacitance, a dielectric constant of the wiring layer will be a design parameter.

For example, a capacitance value can be controlled by forming the wiring layer (e.g., a layer such as the insulating layer 14c and the insulating layer 24c (FIG. 23)) using an insulating film material having a high dielectric constant when it is desired to increase the capacitance related to the wiring (wiring node capacitance), and using an insulating film material having a low dielectric constant when it is desired to decrease the capacitance related to the wiring. In the pixel chip of the semiconductor substrate 10, for example, it is sometimes desired to decrease a parasitic capacitance C1 of the horizontal signal line (drive wiring) 101. In the circuit chip of the semiconductor element 20B, for example, it is sometimes desired to increase a phase compensation capacitance C2 of the ADC 120 in a narrow area. Note that, for example, the phase compensation capacitance C2 of the horizontal signal line 101 and the ADC 120 is formed in a Cu—Cu connection wiring layer.

As illustrated in FIG. 23, the insulating layer 14c of the semiconductor substrate 10 is formed of, for example, an insulating film material having a lower dielectric constant than the dielectric constant of the insulating layer 14a, the insulating layer 14b, and the like. As a result, the parasitic capacitance C1 between the horizontal signal lines 101 can be reduced. Therefore, for example, it is possible to realize a decrease in a drive wiring capacitance and an increase in a drive speed, which are required to be driven at a high speed such as in an indirect time of flight (iToF). As an insulating film material having the low-dielectric-constant, for example, SiO2 having a relative dielectric constant of 3.8 or the like can be used.

Furthermore, the insulating layer 24c of the semiconductor element 20B is formed of, for example, an insulating film material having a higher dielectric constant than the dielectric constant of the insulating layer 24a, the insulating layer 24b, and the like. As a result, for example, the phase compensation capacitance C2 between the wirings 121 can be increased. Therefore, it is possible to achieve a large capacitance for the phase compensation capacitance C2. In addition, for example, it is possible to decrease a cutoff frequency of a low-pass filter or reduce a capacitance area. As the insulating film material having the high dielectric constant, for example, SiN having a relative dielectric constant of 7.8 or SiCN having a relative dielectric constant of 8.0 can be used.

As illustrated in FIG. 24, the pixel 100 may include, for example, a plurality of transistors 100a and a photodiode 100b. Each of the transistors 100a includes a transfer transistor, a reset transistor, an amplification transistor, a selection transistor, and the like. Each of the transistors 100a configures a pixel circuit. The photodiode 100b is an example of a photoelectric conversion element that generates a charge of an amount corresponding to a receiving light quantity, and accumulates the generated charge therein.

The ADC 120 may include a load current source 120a, a comparator 120b, and a counter 120c. A reference voltage generation unit 120d is connected to the comparator 120b. The reference voltage generation unit 120d applies a reference voltage to the comparator 120b. Note that, in the example in FIG. 24, a bonding interface M1 between the pixel chip of the semiconductor substrate 10 and the circuit chip of the semiconductor element 20B is illustrated.

As illustrated in FIG. 25, the comparator 120b may include a plurality of transistors 122 and the phase compensation capacitance C2. In other words, the phase compensation capacitance C2 in the ADC 120 may be a capacitance in the comparator 120b. The plurality of transistors 122 includes, for example, P-channel and N-channel transistors.

As illustrated in FIG. 26, the comparator 120b compares the pixel signal (e.g., voltage waveform) input from the vertical signal line 102 with a reference voltage provided from the reference voltage generation unit 120d, and generates a pulse signal. The counter 120c performs, for example, P-phase counting or D-phase counting, and measures a pulse width of the pulse signal.

According to the present embodiment, the dielectric constant of the insulating layer 14c of the semiconductor substrate 10 is different from the dielectric constant of the insulating layer 14a, the insulating layer 14b, and the like. For example, the dielectric constant of the insulating layer 14c of the semiconductor substrate 10 is lower than the dielectric constant of the insulating layer 14a, the insulating layer 14b, and the like. In addition, the dielectric constant of the insulating layer 24c of the semiconductor element 20B is different from the dielectric constant of the insulating layer 24a, the insulating layer 24b, and the like. For example, the dielectric constant of the insulating layer 24c of the semiconductor element 20B is higher than the dielectric constant of the insulating layer 24a, the insulating layer 24b, and the like. This makes it possible to adjust the capacitance such as the parasitic capacitance C1 and the phase compensation capacitance C2 while improving the bonding strength. For example, the parasitic capacitance C1 can be decreased, and the phase compensation capacitance C2 can be increased. The dielectric constants of the insulating layer 14a, the insulating layer 14b, the insulating layer 24a, and the insulating layer 24b are, for example, the same, but may be different.

In the above description, the present embodiment is applied to the fourth embodiment, but may be applied to other embodiments such as the first and second embodiments. For example, the configuration of the present embodiment is applied to the semiconductor elements 20B and 20C according to other embodiments such as the first and second embodiments. In the present embodiment, the insulating layer (e.g., the insulating layer 14c, the insulating layer 24c, and the like) for achieving improvement in the bonding strength and adjusting the capacitance is provided, but the insulating layer for improving the bonding strength and the insulating layer for adjusting the capacitance may be laminated and provided. In this case, for example, the dielectric constant of the insulating layer for adjusting the capacitance is different from the dielectric constant of other insulating layers (e.g., the insulating layer 14a, the insulating layer 14b, the insulating layer 24a, the insulating layer 24b, and the like). In addition, for example, the insulating layer for improving the bonding strength is located closer to the semiconductor substrate 10 than the insulating layer for adjusting the capacitance.

### 8. Eighth Embodiment

### 8-1. Configuration Example of Semiconductor Device

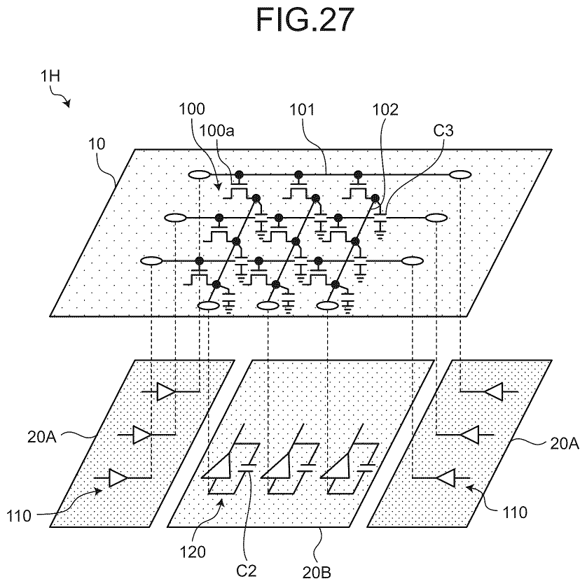

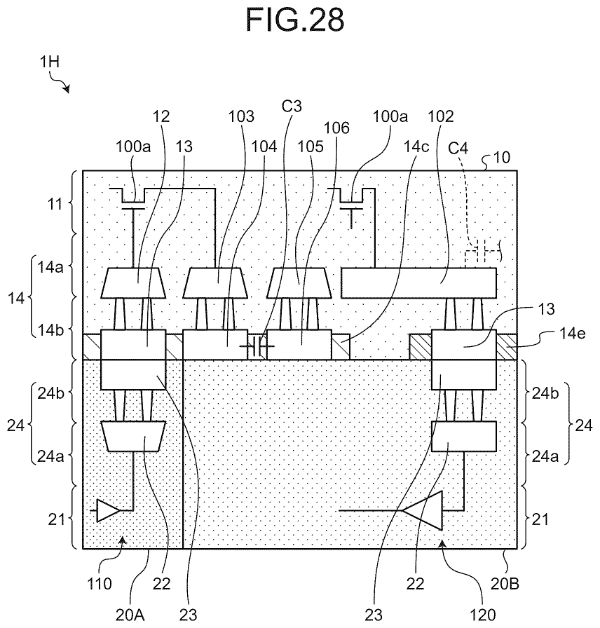

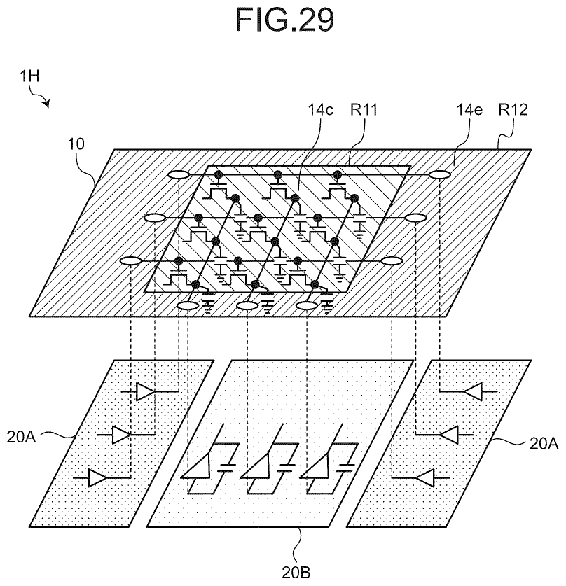

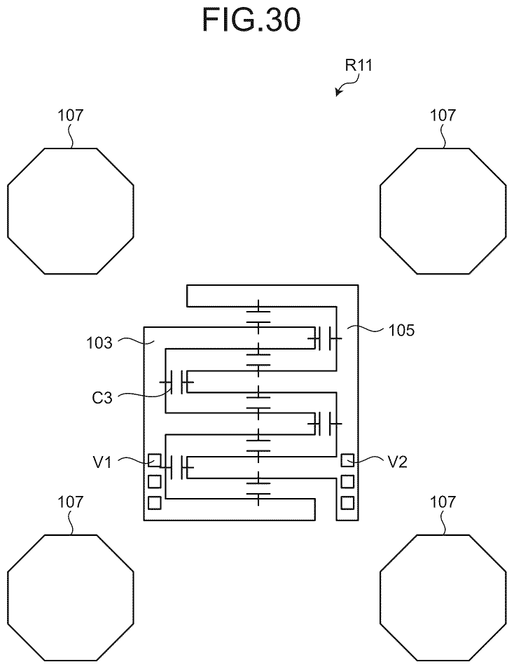

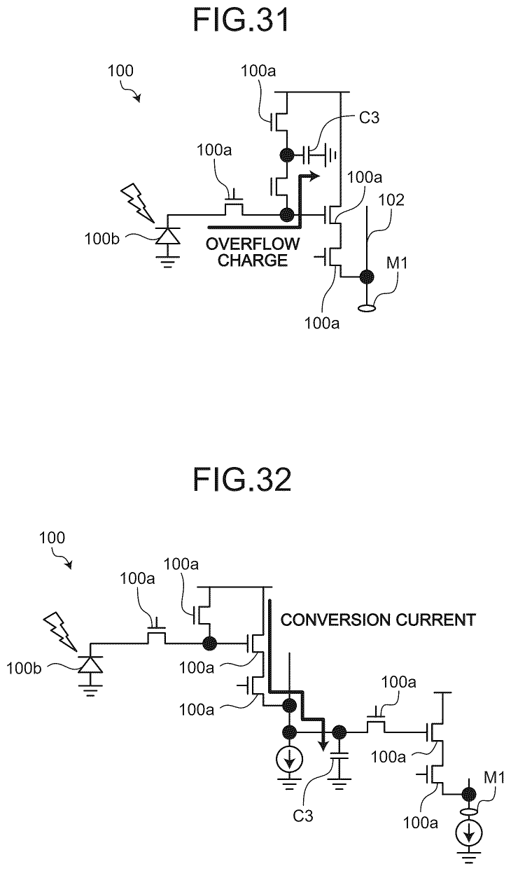

A configuration example of a semiconductor device 1H according to the present embodiment will be described with reference to FIGS. 27 to 32. FIG. 27 is a perspective view illustrating the configuration example of the semiconductor device 1H according to the present embodiment. FIG. 28 is a cross-sectional view illustrating the configuration example of the semiconductor device 1H according to the present embodiment. FIG. 29 is a perspective view illustrating exemplary regions of a pixel region R11 and a connection region R12 of the semiconductor device 1H according to the present embodiment. FIG. 30 is a plan view illustrating a configuration example of wiring of the semiconductor device 1H according to the present embodiment. FIG. 31 is a diagram illustrating a circuit example of the semiconductor device 1H according to the present embodiment. FIG. 32 is a diagram illustrating another circuit example of the semiconductor device 1H according to the present embodiment. In the present embodiment, parts basically different from those of the third and eighth embodiments will be described.

As illustrated in FIG. 27, in the semiconductor device 1H according to the present embodiment, as in the eighth embodiment, for example, the semiconductor substrate 10 is a pixel chip including a plurality of pixels 100. Each of two semiconductor elements 20A is a circuit chip including a plurality of drivers 110. The semiconductor element 20B is a circuit chip including the ADC 120. These pixel chip, circuit chip, and the like may include other elements, circuits, and the like. Note that, in the example in FIG. 28, a plurality of in-pixel wirings 103 and 104 and a plurality of power supply wirings 105 and 106 are illustrated.

Here, for example, as in the eighth embodiment, a capacitance value can be controlled by forming a wiring layer (e.g., a layer such as the insulating layer 14c and the insulating layer 14e (FIG. 28)) using an insulating film material having a high dielectric constant when it is desired to increase the capacitance related to the wiring (wiring node capacitance), and using an insulating film material having a low dielectric constant when it is desired to reduce the capacitance related to the wiring. In the pixel chip of the semiconductor substrate 10, for example, there is a case where it is desired to increase an in-pixel capacitance C3 with a narrow area and to reduce a parasitic capacitance C4 of the vertical signal line 102. Note that, for example, the in-pixel capacitance C3 is formed in a Cu—Cu connection wiring layer.

As illustrated in FIGS. 28 and 29, the insulating layer 14c of the semiconductor substrate 10 is provided in the pixel region R11 (FIG. 29) of the semiconductor substrate 10. The insulating layer 14c is formed of, for example, an insulating film material (e.g., SiN or SiCN) having a higher dielectric constant than the dielectric constant of the insulating layer 14a, the insulating layer 14b, and the like. This makes it possible to increase the in-pixel capacitance C3. Therefore, it is possible to achieve a large capacitance for the in-pixel capacitance C3. In other words, it is possible to increase the charge holding capacitance of the pixel 100.

The Insulating layer 14e of the semiconductor substrate 10 is provided in the connection region R12 (FIG. 29) of the semiconductor substrate 10. The insulating layer 14e is formed of, for example, an insulating film material (e.g., SiO2) having a lower dielectric constant than the dielectric constant of the insulating layer 14a, the insulating layer 14b, and the like. As a result, the parasitic capacitance C4 of the vertical signal line 102 can be reduced.

As illustrated in FIG. 30, in the pixel region R11, for example, each of the in-pixel wirings 103 and 104 and each of the power supply wirings 105 and 106 may be formed in a comb shape, and each of the comb-shaped in-pixel wirings 103 and 104 and each of the comb-shaped power supply wirings 105 and 106 may be provided so as to be combined with each other. This makes it possible to increase the in-pixel capacitance C3. Note that the in-pixel wiring 103 is an upper layer wiring, the in-pixel wiring 104 is a lower layer wiring, the power supply wiring 105 is the upper layer wiring, and the power supply wiring 106 is the lower layer wiring (FIG. 29).

The comb-shaped in-pixel wirings 103 and 104 and the comb-shaped power supply wirings 105 and 106 are provided avoiding a plurality of connection points 107. In other words, as the wiring layout (e.g., a wiring shape in plan view) in the pixel region R11, a wiring layout having a comb shape or the like avoiding the connection points 107 is effective. In the example in FIG. 30, four connection points 107 are illustrated. Each of the connection points 107 is, for example, a Cu—Cu connection point. The connection points 107 may include, for example, a dummy connection point (dummy layout).

Each of the comb-shaped in-pixel wirings 103 and 104 is connected by a plurality of vias V1. Each of the comb-shaped power supply wirings 105 and 106 is also connected by a plurality of vias V2. Each of the vias V1 is a via connecting the in-pixel wirings 103 and 104 having the comb-shape. Each of the vias V2 is a via connecting the power supply wirings 105 and 106 having the comb-shape.

As illustrated in FIG. 31, the in-pixel capacitance C3 may be, for example, an in-pixel charge holding capacitance that serves to receive an overflow charge from the photodiode 100b. As the capacitance is larger, a larger light quantity signal can also be read.

Furthermore, as illustrated in FIG. 32, the in-pixel capacitance C3 may be, for example, an in-pixel charge holding capacitance that collectively transfers and holds the charge of the photodiode 100b in all rows in a voltage domain global shutter (VDGS). The VDGS is an imaging method of collectively transferring and holding charges of the photodiode 100b in all rows. The larger the capacity to retain this charge, the smaller the influence of leakage during holding.

According to the present embodiment, the dielectric constant of the insulating layer 14c of the semiconductor substrate 10 is different from the dielectric constant of the insulating layer 14a, the insulating layer 14b, and the like. For example, the dielectric constant of the insulating layer 14c of the semiconductor substrate 10 is higher than the dielectric constant of the insulating layer 14a, the insulating layer 14b, and the like. In addition, the dielectric constant of the insulating layer 14e of the semiconductor substrate 10 is different from the dielectric constant of the insulating layer 14a, the insulating layer 14b, and the like. For example, the dielectric constant of the insulating layer 14e of the semiconductor substrate 10 is lower than the dielectric constant of the insulating layer 14a, the insulating layer 14b, and the like. This makes it possible to adjust the capacitance such as the in-pixel capacitance C3 and the parasitic capacitance C4 while improving the bonding strength. For example, it is possible to increase the capacitance of the in-pixel capacitance C3 and decrease the parasitic capacitance C4.

In the above description, the present embodiment is applied to the third embodiment, but may be applied to other embodiments such as the first and second embodiments. For example, the configuration of the present embodiment is applied to the semiconductor elements 20B and 20C according to other embodiments such as the first and second embodiments. Also in the present embodiment, similarly to the eighth embodiment, the insulating layer (e.g., the insulating layer 14c and the insulating layer 14e) for improving the bonding strength and adjusting the capacitance is provided, but the insulating layer for improving the bonding strength and the insulating layer for adjusting the capacitance may be laminated and provided.

### 9. Functions and Effects According to Each Embodiment

As described above, according to the embodiments, the semiconductor device (e.g., any one of the semiconductor devices 1A to 1H) includes the semiconductor substrate 10 including the first insulating layer 14 and the plurality of first terminals 13 provided on the first insulating layer 14, and the semiconductor element 20 laminated on the semiconductor substrate 10 and including the second insulating layer 24 and the plurality of second terminals 23 provided on the second insulating layer 24 and connected to the plurality of first terminals 13. The first insulating layer 14 or the second insulating layer 24 includes the third insulating layer (e.g., the insulating layer 24c, the insulating layer 14c, and the insulating layer 14d) that is formed of the material different from that of the first insulating layer 14 and bonds the semiconductor substrate 10 and the semiconductor element 20. As a result, at the time of bonding the semiconductor substrate 10 and the semiconductor element 20, the first insulating layer 14 or the second insulating layer 24 and the third insulating layer are bonded, and the bonding strength can be improved as compared with a case where the first insulating layer 14 and the second insulating layer 24 are directly bonded as in the normal case. For example, the material of the third insulating layer can be appropriately changed according to necessary bonding strength.

Still more, the second insulating layer 24 may include the third insulating layer (e.g., the insulating layer 24c). Even with this configuration, the bonding strength can be improved.

Still more, the third insulating layer may be formed in the entire region of the surface of the semiconductor element 20 on the side of the semiconductor substrate 10 while avoiding the plurality of second terminals 23. This makes it possible to reliably improve the bonding strength.

Still more, the semiconductor element 20 may have the first region (e.g., dense region R1) in which some of the plurality of second terminals 23 are provided at the first pitch and the second region (e.g., sparse region R2) in which some of the plurality of second terminals 23 are provided at the second pitch wider than the first pitch, and the third insulating layer may be formed in the second region. This makes it possible to reliably improve the bonding strength.

Still more, the third insulating layer may be formed in the outer peripheral region R4 of the surface of the semiconductor element 20 on the side of the semiconductor substrate 10. This makes it possible to reliably improve the bonding strength. For example, since it is possible to suppress peeling that is likely to occur in the outer peripheral region R4 of the semiconductor element 20, it is possible to reliably improve the bonding strength.

The first insulating layer 14 may include the third insulating layer (e.g., the insulating layer 14c and the insulating layer 14d). Even with this configuration, the bonding strength can be improved.

Still more, the third insulating layer may be formed in the region facing the semiconductor element 20 that is a region of the surface of the semiconductor substrate 10 on the side of the semiconductor element 20. This makes it possible to reliably improve the bonding strength.

Still more, the semiconductor element 20 may have the first region (e.g., dense region R1) in which some of the plurality of second terminals 23 are provided at the first pitch and the second region (e.g., sparse region R2) in which some of the plurality of second terminals 23 are provided at the second pitch wider than the first pitch. The third insulating layer may be formed in a region facing the second region that is the region of the surface of the semiconductor substrate 10 on the side of the semiconductor element 20. This makes it possible to reliably improve the bonding strength.

In addition, the third insulating layer may be formed in the region facing the outer peripheral region R4 of the surface of the semiconductor element 20 on the side of the semiconductor substrate 10, which is the region of the surface of the semiconductor substrate 10 on the side of the semiconductor element 20. This makes it possible to reliably improve the bonding strength. For example, since it is possible to suppress peeling that is likely to occur in the outer peripheral region R4 of the semiconductor element 20, it is possible to reliably improve the bonding strength.

The dielectric constant of the third insulating layer (e.g., the insulating layer 14c, the insulating layer 14e, and the insulating layer 24c) may be different from the dielectric constant of the first insulating layer 14 or the second insulating layer 24. As a result, for example, various capacitances such as the parasitic capacitance C1, the phase compensation capacitance C2, the in-pixel capacitance C3, and the parasitic capacitance C4 can be adjusted.

In addition, each of the first insulating layer 14 and the second insulating layer 24 may have the third insulating layer (e.g., the insulating layer 14c, the insulating layer 14d, and the insulating layer 24c). Even with this configuration, the bonding strength can be improved.

Still more, the plurality of third insulating layers may be provided at positions facing each other. This makes it possible to reliably improve the bonding strength.

Still more, the dielectric constant of the third insulating layer (e.g., insulating layer 14c) included in the first insulating layer 14 may be different from the dielectric constant of the first insulating layer 14, and the dielectric constant of the third insulating layer (e.g., insulating layer 24c) included in the second insulating layer 24 may be different from the dielectric constant of the second insulating layer 24. As a result, for example, various capacitances such as the parasitic capacitance C1, the phase compensation capacitance C2, the in-pixel capacitance C3, and the parasitic capacitance C4 can be adjusted.

Still more, the material of the third insulating layer may be determined such that the bonding strength of the third insulating layer between the semiconductor substrate 10 and the semiconductor element 20 increases as the size of the semiconductor element 20 is decreased. This makes it possible to reliably improve the bonding strength.

Still more, the material or thickness of the third insulating layer may be determined such that the withstand voltage between the plurality of second terminals 23 due to the third insulating layer increases as the pitch of the plurality of second terminals 23 is narrowed. As a result, it is possible to improve the withstand voltage.

Still more, the plurality of semiconductor elements 20 may be provided, and the third insulating layer may be provided for each of the semiconductor elements 20. As a result, in each of the semiconductor elements 20, the bonding strength can be improved.

Still more, the material of the third insulating layer for each semiconductor element 20 may be different for each semiconductor element 20. As a result, in each semiconductor element 20, the bonding strength can be reliably improved.

Further, the material of the third insulating layer for each of the semiconductor elements 20 is determined so as to suppress distortion caused by a difference in the CTE among the plurality of semiconductor elements 20. This makes it possible to suppress distortion in the semiconductor device (e.g., any one of the semiconductor devices 1A to 1H) including the plurality of semiconductor elements 20.

### 10. Application Example

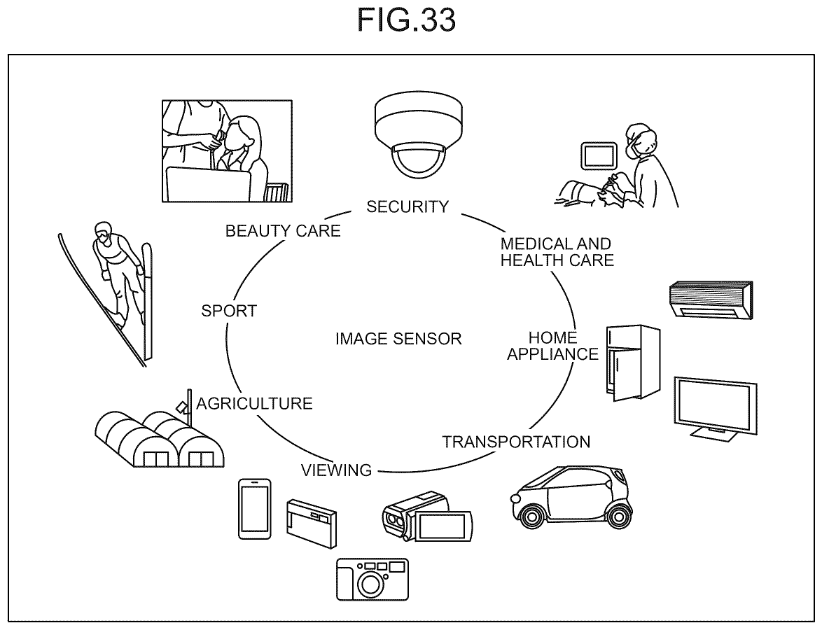

Next, an application example of the semiconductor devices 1A to 1H according to the embodiments is explained. FIG. 33 is a diagram illustrating a use example in which the semiconductor devices 1A to 1H according to the embodiments is used.

The semiconductor devices 1A to 1H explained above can be used, for example, in various cases in which light such as visible light, infrared light, ultraviolet light, and an X-ray are sensed as explained below. For example, as illustrated in FIG. 33, the semiconductor devices 1A to 1H is used for “a device that captures an image served for use of viewing such as a digital camera or a portable device with a camera function”, “a device served for use of traffic such as an in-vehicle sensor that images the front and the rear, surroundings, interior, and the like of an automobile for safe driving such as automatic stop, recognition of a driver's condition, and the like, a monitoring camera that monitors traveling vehicles and roads, and a distance measuring sensor that measures a distance between vehicles and the like”, “a device served for home electric appliances such as a TV, a refrigerator, and an air conditioner in order to capture an image of a gesture of a user and perform an equipment operation conforming to the gesture”, “a device served for use in medical care or health care such as an endoscope or a device that performs angiography by receiving infrared light”, “a device served for use in security such as a monitoring camera for crime prevention use or a camera for person authentication”, “a device served for use in beauty care such as a skin measuring instrument for imaging skin or a microscope for imaging scalp”, “a device served for use in sports such as an action camera or a wearable camera for sports use or the like”, “a device served for use in agriculture such as a camera for monitoring conditions of fields and crops”, and the like.

Note that the technique according to the present disclosure can be applied to various products. For example, the technique according to the present disclosure may be realized as a device (e.g., an electronic apparatus) mounted on any type of mobile body such as an automobile, an electric vehicle, a hybrid electric vehicle, a motorcycle, a bicycle, a personal mobility, an airplane, a drone, a ship, a robot, a construction machine, or an agricultural machine (a tractor). For example, the technique according to the present disclosure may be realized as a device (e.g., an electronic apparatus) mounted on an endoscopic surgical system, a microscopic surgical system, and the like.

### 11. Electronic Apparatus According to Application Example

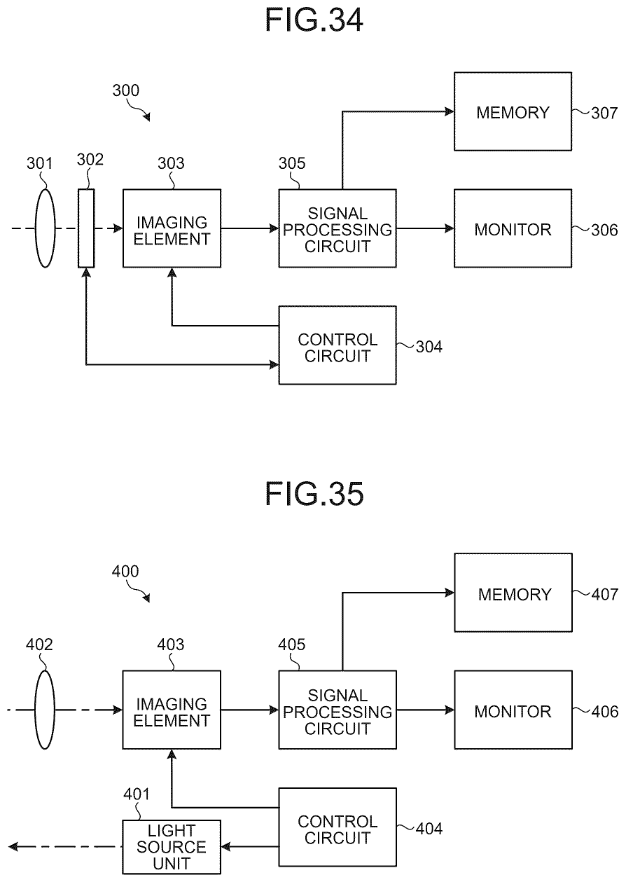

As an electronic apparatus to which any one of the above-described semiconductor devices 1A to 1H is applied, an imaging device 300 and a distance measuring device 400 will be described with reference to FIGS. 34 and 35.

### 11-1. Imaging Device

The imaging device 300 according to the application example will be described with reference to FIG. 34. FIG. 34 is a diagram illustrating an example of a schematic configuration of the imaging device 300 according to the application example. The imaging device 300 is an example of the electronic apparatus to which any one of the above-described semiconductor devices 1A to 1H is applied. Examples of the imaging device 300 include electronic devices such as a digital still camera, a video camera, a smartphone having an imaging function, and a mobile phone.

As illustrated in FIG. 34, the imaging device 300 includes an optical system 301, a shutter device 302, an imaging element (a solid-state imaging device) 303, a control circuit (drive circuit) 304, a signal processing circuit 305, a monitor 306, and a memory 307. The imaging device 300 can capture a still image and a moving image.

The optical system 301 includes one or a plurality of lenses. The optical system 301 guides light (incident light) from a subject to the imaging element 303 and forms an image on a light receiving surface of the imaging element 303.

The shutter device 302 is disposed between the optical system 301 and the imaging element 303. The shutter device 302 controls a light irradiation period and a light shielding period with respect to the imaging element 303 according to the control of the control circuit 304.

The imaging element 303 accumulates signal charges for a certain period according to light formed on the light receiving surface via the optical system 301 and the shutter device 302. The signal charges accumulated in the imaging element 303 is transferred in accordance with a drive signal (timing signal) supplied from the control circuit 304.

The control circuit 304 outputs the drive signal for controlling a transfer operation of the imaging element 303 and a shutter operation of the shutter device 302 to drive the imaging element 303 and the shutter device 302.

The signal processing circuit 305 performs various types of signal processing on the signal charges output from the imaging element 303. An image (image data) obtained by performing the signal processing by the signal processing circuit 305 is supplied to the monitor 306 and also supplied to the memory 307.

The monitor 306 displays a moving image or a still image captured by the imaging element 303 based on the image data supplied from the signal processing circuit 305. As the monitor 306, for example, a panel type display device such as a liquid crystal panel or an organic electro luminescence (EL) panel is used.

The memory 307 stores the image data supplied from the signal processing circuit 305, that is, the image data of the moving image or the still image captured by the imaging element 303.

Also in the imaging device 300 configured in this manner, the bonding strength, that is, the quality can be improved by applying any one of the semiconductor devices 1A to 1H to each part such as the imaging element 303, the signal processing circuit 305, the memory 307, and the like.

### 11-2. Distance Measuring Device

The distance measuring device 400 according to the application example will be described with reference to FIG. 35. FIG. 35 is a diagram illustrating an example of a schematic configuration of the distance measuring device 400 according to the application example. The distance measuring device 400 is an example of the electronic apparatus to which any one of the above-described semiconductor devices 1A to 1H is applied.

As illustrated in FIG. 35, the distance measuring device (distance image sensor) 400 includes a light source unit 401, an optical system 402, an imaging element (a solid-state imaging device) 403, a control circuit (drive circuit) 404, a signal processing circuit 405, a monitor 406, and a memory 407. The distance measuring device 400 can acquire a distance image according to a distance to a subject by projecting light from the light source unit 401 toward the subject and receiving light (modulated light or pulsed light) reflected from a surface of the subject.

The light source unit 401 projects light toward the subject. As the light source unit 401, for example, a vertical cavity surface emitting laser (VCSEL) array that emits laser light as a surface light source or a laser diode array in which laser diodes are arrayed on a line is used. Note that the laser diode array is supported by a predetermined drive unit (not illustrated), and is scanned in a direction perpendicular to the array direction of the laser diodes.

The optical system 402 includes one or a plurality of lenses. The optical system 402 guides light (incident light) from the subject to the imaging element 403 to form an image on a light receiving surface (sensor unit) of the imaging element 403.

The imaging element 403 stores signal charges according to the light of the image formed on the light receiving surface via the optical system 402. A distance signal indicating the distance obtained from a light reception signal (APD OUT) output from the imaging element 403 is supplied to the signal processing circuit 405. As the imaging element 403, for example, a solid-state imaging element such as an image sensor is used.

The control circuit 404 outputs a drive signal (control signal) for controlling operations of the light source unit 401, the imaging element 403, and the like to drive the light source unit 401, the imaging element 403, and the like.

The signal processing circuit 405 performs various types of signal processing on the distance signal supplied from the imaging element 403. For example, the signal processing circuit 405 performs image processing (for example, histogram processing, peak detection processing, and the like) of constructing the distance image on the basis of the distance signal. An image (image data) obtained by performing the signal processing by the signal processing circuit 405 is supplied to the monitor 406 and also supplied to the memory 407.

The monitor 406 displays the distance image captured by the imaging element 303 on the basis of the image data supplied from the signal processing circuit 405. As the monitor 406, for example, a panel type display device such as a liquid crystal panel or an organic EL panel is used.

The memory 407 stores the image data supplied from the signal processing circuit 405, that is, the image data of the distance image captured by the imaging element 303.

Also in the distance measuring device 400 configured in this manner, the bonding strength, that is, the quality can be improved by applying any one of the semiconductor devices 1A to 1H to each part such as the imaging element 403, the signal processing circuit 405, the memory 407, and the like.

Note that, the above-described semiconductor devices 1A to 1H can be mounted on various electronic devices as described above. For example, the semiconductor devices 1A to 1H may be mounted on various electronic devices such as a hard disk drive (HDD), a notebook personal computer (PC), a mobile device (for example, a smartphone, a tablet PC, or the like), a personal digital assistant (PDA), a wearable device, a game device, and a music device in addition to the imaging device 300 and the distance measuring device 400.

### 12. Other Embodiments

The configuration according to the above embodiments may be implemented in various different forms other than the above embodiments. For example, the configuration is not limited to the above-described examples, and may be implemented in various modes. Furthermore, for example, the configuration, the processing procedure, the specific names, and the information including various data and parameters illustrated in the above document and the drawings can be arbitrarily changed unless otherwise specified.

In addition, each component of each device illustrated in the drawings is functionally conceptual, and is not necessarily physically configured as illustrated in the drawings. In other words, a specific form of distribution and integration of each device is not limited to the illustrated form, and all or a part thereof can be functionally or physically distributed and integrated in an arbitrary unit according to various loads, usage conditions, and the like.

Further, the above-described embodiments (or modifications) can be appropriately combined within a range not contradicting processes. Note that the effects described in the present specification are merely examples and not limited, and other effects may be provided.

### 13. Appendix

The present technology may also have the following configurations.
(1)
   A semiconductor device comprising:
      a semiconductor substrate including a first insulating layer and a plurality of first terminals provided on the first insulating layer; and
      a semiconductor element laminated on the semiconductor substrate, the semiconductor element including a second insulating layer and a plurality of second terminals provided on the second insulating layer and connected to the plurality of first terminals, respectively, wherein the first insulating layer or the second insulating layer includes a third insulating layer formed of a material different from a material of the first insulating layer and bonding the semiconductor substrate and the semiconductor element.
(2)
   The semiconductor device according to (1), wherein
      the second insulating layer includes the third insulating layer.
(3)
   The semiconductor device according to (2), wherein
      the third insulating layer is formed in an entire region of a surface of the semiconductor element on a side of the semiconductor substrate, the third insulating layer being formed avoiding the plurality of second terminals.
(4)
   The semiconductor device according to (2), wherein
      the semiconductor element has a first region in which some of the plurality of second terminals are provided at a first pitch and a second region in which some of the plurality of second terminals are provided at a second pitch wider than the first pitch, and
      the third insulating layer is formed in the second region.
(5)
   The semiconductor device according to (2), wherein
      the third insulating layer is formed in an outer peripheral region of a surface of the semiconductor element on a side of the semiconductor substrate.
(6)
   The semiconductor device according to (1), wherein
      the first insulating layer includes the third insulating layer.
(7)
   The semiconductor device according to (6), wherein
      the third insulating layer is formed in a region of a surface of the semiconductor substrate on a side of the semiconductor element, the region facing the semiconductor element.
(8)
   The semiconductor device according to (6), wherein
      the semiconductor element has a first region in which some of the plurality of second terminals are provided at a first pitch and a second region in which some of the plurality of second terminals are provided at a second pitch wider than the first pitch, and
      the third insulating layer is formed in a region of a surface of the semiconductor substrate on a side of the semiconductor element, the region facing the second region.
(9)
   The semiconductor device according to (6), wherein
      the third insulating layer is formed in a region of a surface of the semiconductor substrate on a side of the semiconductor element, the region facing an outer peripheral region of a surface of the semiconductor element on a side of the semiconductor substrate.
(10)
   The semiconductor device according to any one of (1) to (9), wherein
      the third insulating layer has a dielectric constant different from a dielectric constant of the first insulating layer or the second insulating layer.
(11)
   The semiconductor device according to (1), wherein
      the first insulating layer and the second insulating layer each include the third insulating layer.
(12)
   The semiconductor device according to (11), wherein
      a plurality of the third insulating layers is provided at positions facing each other.
(13)
   The semiconductor device according to (11) or (12), wherein
      the third insulating layer included in the first insulating layer has a dielectric constant different from a dielectric constant of the first insulating layer, and the third insulating layer included in the second insulating layer has a dielectric constant different from a dielectric constant of the second insulating layer.
(14)
   The semiconductor device according to any one of (1) to (13), wherein
      a material of the third insulating layer is determined to increase a bonding strength of the third insulating layer between the semiconductor substrate and the semiconductor element as a size of the semiconductor element is decreased.
(15)
   The semiconductor device according to any one of (1) to (13), wherein
      a material or a thickness of the third insulating layer is determined to increase a withstand voltage of the third insulating layer between the plurality of second terminals as a pitch of the plurality of second terminals is narrowed.
(16)
   The semiconductor device according to (1), wherein
      a plurality of the semiconductor elements is provided, and
      the third insulating layer is provided for each of the plurality of semiconductor elements.
(17)
   The semiconductor device according to (16), wherein
      a material of the third insulating layer for each of the plurality of semiconductor elements is different for the each of the plurality of semiconductor elements.
(18)
   The semiconductor device according to (17), wherein
      the material of the third insulating layer for the each of the plurality of semiconductor elements is determined so as to suppress distortion caused by a difference in a thermal expansion coefficient between the plurality of semiconductor elements.
(19)
   An electronic apparatus comprising a semiconductor device, the semiconductor device including:
      a semiconductor substrate having a first insulating layer and a plurality of first terminals provided on the first insulating layer; and
      a semiconductor element laminated on the semiconductor substrate, the semiconductor element having a second insulating layer and a plurality of second terminals provided on the second insulating layer and connected to the plurality of first terminals, respectively, wherein
      the first insulating layer or the second insulating layer includes a third insulating layer formed of a material different from a material of the first insulating layer and bonding the semiconductor substrate and the semiconductor element.
(20)
   A semiconductor device manufacturing method comprising:
      laminating, on a semiconductor substrate having a first insulating layer and a plurality of first terminals provided on the first insulating layer, a semiconductor element having a second insulating layer and a plurality of second terminals provided on the second insulating layer and connected to the plurality of first terminals, respectively, wherein
      the laminating the semiconductor element on the semiconductor substrate includes bonding the semiconductor substrate and the semiconductor element by a third insulating layer formed of a material different from the first insulating layer and included in the first insulating layer or the second insulating layer.
(21)
   An electronic apparatus including the semiconductor device according to any one of (1) to (18).
(22)
   A semiconductor device manufacturing method, in which the semiconductor device according to any one of (1) to (18) is manufactured.

### REFERENCE SIGNS LIST

1A SEMICONDUCTOR DEVICE
1B SEMICONDUCTOR DEVICE
1C SEMICONDUCTOR DEVICE
1D SEMICONDUCTOR DEVICE
1E SEMICONDUCTOR DEVICE
1F SEMICONDUCTOR DEVICE
1G SEMICONDUCTOR DEVICE
1H SEMICONDUCTOR DEVICE
10 SEMICONDUCTOR SUBSTRATE
11 SUBSTRATE
12 CIRCUIT ELEMENT
13 TERMINAL
14 INSULATING LAYER
14a INSULATING LAYER
14b INSULATING LAYER
14c INSULATING LAYER
14d INSULATING LAYER
14e INSULATING LAYER
20 SEMICONDUCTOR ELEMENT
20A FIRST SEMICONDUCTOR ELEMENT
20B SECOND SEMICONDUCTOR ELEMENT
20C THIRD SEMICONDUCTOR ELEMENT
21 SUBSTRATE
22 CIRCUIT ELEMENT
23 TERMINAL
24 INSULATING LAYER
24a INSULATING LAYER
24b INSULATING LAYER
24c INSULATING LAYER
100 PIXEL
100a TRANSISTOR
100b PHOTODIODE
101 SIGNAL LINE
102 SIGNAL LINE
103 IN-PIXEL WIRING
104 IN-PIXEL WIRING
105 POWER SUPPLY WIRING
106 POWER SUPPLY WIRING
107 CONNECTION POINT
110 DRIVER
120 ADC
120a LOAD CURRENT SOURCE
120b COMPARATOR
120c COUNTER
120d REFERENCE VOLTAGE GENERATION UNIT
121 WIRING
122 TRANSISTOR
300 IMAGING DEVICE
400 DISTANCE MEASURING DEVICE
A1 CHIP
A2 CHIP
C1 PARASITIC CAPACITANCE
C2 PHASE COMPENSATION CAPACITANCE
C3 IN-PIXEL CAPACITANCE
C4 PARASITIC CAPACITANCE
R1 DENSE REGION
R2 SPARSE REGION
R3 CENTRAL REGION
R4 OUTER PERIPHERAL REGION
R11 PIXEL REGION
R12 CONNECTION REGION
V1 VIA
V2 VIA
W1 WAFER
W2 WAFER
W3 WAFER
W4 WAFER
W5 WAFER
W6 WAFER

What is claimed is:

1. A semiconductor device, comprising:
a semiconductor substrate including a first insulating layer and a plurality of first terminals provided on the first insulating layer; and
a semiconductor element laminated on the semiconductor substrate, the semiconductor element including a second insulating layer and a plurality of second terminals provided on the second insulating layer and connected to the plurality of first terminals, respectively, wherein
the first insulating layer or the second insulating layer includes a third insulating layer formed of a material different from a material of the first insulating layer and bonding the semiconductor substrate and the semiconductor element.

2. The semiconductor device according to claim 1, wherein
the second insulating layer includes the third insulating layer.

3. The semiconductor device according to claim 2, wherein
the third insulating layer is formed in an entire region of a surface of the semiconductor element on a side of the semiconductor substrate, the third insulating layer being formed avoiding the plurality of second terminals.

4. The semiconductor device according to claim 2, wherein
the semiconductor element has a first region in which some of the plurality of second terminals are provided at a first pitch and a second region in which some of the plurality of second terminals are provided at a second pitch wider than the first pitch, and
the third insulating layer is formed in the second region.

5. The semiconductor device according to claim 2, wherein
the third insulating layer is formed in an outer peripheral region of a surface of the semiconductor element on a side of the semiconductor substrate.

6. The semiconductor device according to claim 1, wherein
the first insulating layer includes the third insulating layer.

7. The semiconductor device according to claim 6, wherein
the third insulating layer is formed in a region of a surface of the semiconductor substrate on a side of the semiconductor element, the region facing the semiconductor element.

8. The semiconductor device according to claim 6, wherein
the semiconductor element has a first region in which some of the plurality of second terminals are provided at a first pitch and a second region in which some of the plurality of second terminals are provided at a second pitch wider than the first pitch, and
the third insulating layer is formed in a region of a surface of the semiconductor substrate on a side of the semiconductor element, the region facing the second region.

9. The semiconductor device according to claim 6, wherein
the third insulating layer is formed in a region of a surface of the semiconductor substrate on a side of the semiconductor element, the region facing an outer peripheral region of a surface of the semiconductor element on a side of the semiconductor substrate.

10. The semiconductor device according to claim 1, wherein
the third insulating layer has a dielectric constant different from a dielectric constant of the first insulating layer or the second insulating layer.

11. The semiconductor device according to claim 1, wherein
the first insulating layer and the second insulating layer each include the third insulating layer.

12. The semiconductor device according to claim 11, wherein
a plurality of the third insulating layers is provided at positions facing each other.

13. The semiconductor device according to claim 11, wherein
the third insulating layer included in the first insulating layer has a dielectric constant different from a dielectric constant of the first insulating layer, and
the third insulating layer included in the second insulating layer has a dielectric constant different from a dielectric constant of the second insulating layer.

14. The semiconductor device according to claim 1, wherein
a material of the third insulating layer is determined to increase a bonding strength of the third insulating layer between the semiconductor substrate and the semiconductor element as a size of the semiconductor element is decreased.

15. The semiconductor device according to claim 1, wherein
a material or a thickness of the third insulating layer is determined to increase a withstand voltage of the third insulating layer between the plurality of second terminals as a pitch of the plurality of second terminals is narrowed.

16. The semiconductor device according to claim 1, wherein
a plurality of the semiconductor elements is provided, and
the third insulating layer is provided for each of the plurality of semiconductor elements.

17. The semiconductor device according to claim 16, wherein
a material of the third insulating layer for each of the plurality of semiconductor elements is different for the each of the plurality of semiconductor elements.

18. The semiconductor device according to claim 17, wherein
the material of the third insulating layer for the each of the plurality of semiconductor elements is determined so as to suppress distortion caused by a difference in a thermal expansion coefficient between the plurality of semiconductor elements.

19. An electronic apparatus comprising a semiconductor device, the semiconductor device including:
a semiconductor substrate having a first insulating layer and a plurality of first terminals provided on the first insulating layer; and
a semiconductor element laminated on the semiconductor substrate, the semiconductor element having a second insulating layer and a plurality of second terminals provided on the second insulating layer and connected to the plurality of first terminals, respectively, wherein
the first insulating layer or the second insulating layer includes a third insulating layer formed of a material different from a material of the first insulating layer and bonding the semiconductor substrate and the semiconductor element.

20. A semiconductor device manufacturing method, comprising:
laminating, on a semiconductor substrate having a first insulating layer and a plurality of first terminals provided on the first insulating layer, a semiconductor element having a second insulating layer and a plurality of second terminals provided on the second insulating layer and connected to the plurality of first terminals, respectively, wherein
the laminating the semiconductor element on the semiconductor substrate includes bonding the semiconductor substrate and the semiconductor element by a third insulating layer formed of a material different from the first insulating layer and included in the first insulating layer or the second insulating layer.
